(19) United States
(12) Patent Application Publication
(10) Pub. No.: US 2025/0255159 A1
(43) Pub. Date: Aug. 7, 2025

(54) LIGHT EMITTING DISPLAY DEVICE

(71) Applicant: Samsung Display Co., Ltd., Yongin-Si (KR)

(72) Inventors: Hae Ju YUN, Yongin-si (KR); Soo-Hye RYU, Yongin-si (KR); Hae Chan PARK, Yongin-si (KR); Baek Min OH, Yongin-si (KR); Eung Gyu LEE, Yongin-si (KR); HYEMIN LEE, Yongin-si (KR); Eun Je JANG, Yongin-si (KR)

(21) Appl. No.: 18/884,108

(22) Filed: Sep. 13, 2024

(30) Foreign Application Priority Data
Feb. 6, 2024 (KR) 10-2024-0018121

(51) Int. Cl. H10K 59/80; H01L 27/15; H01L 33/50; H01L 33/58; H10K 59/122; H10K 59/38

(52) U.S. Cl. CPC H10K 59/8792; H10H 20/8514; H10H 20/855; H10H 29/142; H10K 59/122; H10K 59/38

(57) ABSTRACT

A light emitting display device is disclosed that includes a substrate, a plurality of anodes disposed on the substrate, a pixel defining layer including a plurality of first openings, a plurality of light emitting layers disposed in the plurality of first openings of the pixel defining layer, an encapsulation layer disposed on a cathode, and a plurality of color filters corresponding to different colors disposed on the encapsulation layer. The plurality of color filters includes a plurality of second openings and a light blocking area of a color filter, which includes at least two color filters overlapped with each other, and a single color filter is disposed in each of the plurality second openings. At least some of the plurality of first openings of the pixel defining layer has an oval shape, and the plurality of second openings of the color filter has a circular shape.

### CROSS-REFERENCE TO RELATED APPLICATION

This application claims priority to and the benefit of Korean Patent Application No. 10-2024-0018121 filed at the Korean Intellectual Property Office on Feb. 6, 2024, the entire contents of which are incorporated herein by reference.

### BACKGROUND

### (a) Field

This present disclosure relates to a light emitting display device.

### (b) Description of the Related Art

A display device is a device that displays a screen and includes a liquid crystal display (LCD) and an organic light emitting diode (OLED) display.

These display devices are used in various electronic devices such as mobile phones, navigation devices, digital cameras, electronic books, portable game consoles, and various terminals.

A display device, such as an organic light emitting display device, may have a structure that allows the display device to be bent or folded using a flexible substrate.

In addition, in small electronic devices such as mobile phones, optical elements such as cameras and optical sensors are disposed in the bezel area around the display area. However, as the size of the display screen increases, the size of the area surrounding the display area gradually decreases, and the camera technology is being developed that allows optical sensors to be positioned on the back of the display area.

### SUMMARY

The embodiments are intended to reduce diffraction patterns caused by the reflection of external light or to lower the reflectance rate. Embodiments are intended to provide a light emitting display device that exhibits minimal color separation of external light or generates a consistent diffraction pattern regardless of the angle.

In addition, the embodiments are to provide a light emitting display device that reduces the diffraction pattern caused by the reflection and transmission of external light by overlapping multiple color filters without forming a black light blocking layer on the front of the display panel, thereby minimizing color separation of external light.

A light emitting display device according to an embodiment includes a substrate, a plurality of anodes disposed on the substrate, a pixel defining layer including a plurality of first openings, each of the plurality of first openings corresponding to each of the plurality of anodes, a plurality of light emitting layers disposed in the plurality of first openings of the pixel defining layer, a cathode disposed on the plurality of light emitting layers and the pixel defining layer, an encapsulation layer disposed on the cathode, and a plurality of color filters corresponding to different colors disposed on the encapsulation layer, wherein the plurality of color filters includes a plurality of second openings and a light blocking area of a color filter, the light blocking area of the color filter includes at least two color filters overlapped with each other, and a single color filter is disposed in each of the plurality of second openings, at least some of the plurality of first openings of the pixel defining layer have an oval shape, and the plurality of second openings of the color filter, which at least partially overlaps the plurality of first openings having the oval shape, has a circular shape.

According to an embodiment, at least a portion of the first opening of the pixel defining layer having the oval shape may overlap the light blocking area of the color filter in a plan view.

According to an embodiment, the second opening of the color filter and the first opening of the pixel defining layer may meet each other at least two times.

According to an embodiment, the second opening of the color filter may be positioned within the first opening of the pixel defining layer having the oval shape in a plan view.

According to an embodiment, a length of a minor axis of the first opening of the pixel defining layer having the oval shape may be shorter than a diameter of the second opening of the color filter, and a length of a major axis of the first opening of the pixel defining layer may be longer than the diameter of the second opening of the color filter.

According to an embodiment, the second opening of the color filter and the first opening of the pixel defining layer may intersect each other at least four times.

According to an embodiment, the first opening of the pixel defining layer having the oval shape may be positioned within the second opening of the color filter having a circular shape in a plan view.

According to an embodiment, the second opening of the color filter and the first opening of the pixel defining layer may meet each other at least two times.

According to an embodiment, the plurality of first openings or the plurality of second openings may include four or more major axis angles, and the angle formed by the major axes of two first openings among the plurality of first openings or the angle formed by the major axes of the two second openings among the plurality of second openings may be 45 degrees or less.

According to an embodiment, each of the plurality of first openings or each of the plurality of second openings may have eccentricity in a range from 0.2 to 0.85.

According to an embodiment, a gap between the first opening and the second opening that overlaps the first opening in a plan view may be in a range from 0 μm to 20 μm.

According to an embodiment, the first opening or the second opening may have a planar shape that merges at least two oval shapes with different eccentricities.

According to an embodiment, the first opening or the second opening may have a planar shape including a first ellipse with first eccentricity and a second ellipse with second eccentricity.

According to an embodiment, the light blocking area of the color filter may include a blue color filter and a red color filter overlapped each other, and each of the plurality of second openings may accommodate one of the blue color filter, the red color filter, and a green color filter.

According to an embodiment, the light blocking area of the color filter may include a blue color filter, a red color filter, and a green color filter overlapped each other, and each of the plurality of second openings may accommodate one of the blue color filter, the red color filter, and the green color filter.

A light emitting display device according to an embodiment includes a substrate, a plurality of anodes disposed on the substrate, a pixel defining layer including a plurality of first openings, each of the plurality of first openings corresponding to each of the plurality of anodes, a plurality of light emitting layers disposed in the plurality of first openings of the pixel defining layer, a cathode disposed on the plurality of light emitting layers and the pixel defining layer, an encapsulation layer disposed on the cathode, and a light blocking layer disposed on the encapsulation layer and including a plurality of second openings, each of the plurality of second openings of the light blocking layer corresponding to each of the plurality of first openings, wherein at least some of the plurality of first openings of the pixel defining layer have an oval shape, and the plurality of second openings of the light blocking layer, which at least partially overlap the plurality of first openings having the oval shape, have a circular shape.

According to an embodiment, at least a portion of the first opening of the pixel defining layer having the oval shape may overlap the light blocking layer in a plan view.

According to an embodiment, the second opening of the light blocking layer may be positioned within the first opening of the pixel defining layer having the oval shape in a plan view.

According to an embodiment, a length of a minor axis of the first opening of the pixel defining layer having the oval shape may be shorter than a diameter of the second opening of the light blocking layer, and a length of a major axis of the first opening of the pixel defining layer may be longer than the diameter of the second opening of the light blocking layer.

According to an embodiment, the first opening of the pixel defining layer having the oval shape may be positioned within the second opening of the light blocking layer having a circular shape in a plan view.

According to embodiments, at least one of the opening of the pixel defining layer and the opening of the color filter is formed in an oval or a similar shape, the angle of the major axis of the oval is arranged in various ways, the eccentricity of the oval is formed in various ways, or the oval is formed in a plurality of shapes. By having a merged structure that combines ellipses with eccentricity, color separation of external light can be reduced, or a constant diffraction pattern can be generated regardless of the angle.

According to embodiments, the diffraction pattern can be reduced by reducing the rate at which external light is reflected by using a black pixel defining layer to separate the light emitting layers from each other instead of the polarizer.

In addition, according to an embodiment, a plurality of color filters is overlapped without forming a black light blocking layer on the front of the display panel to prevent external light from being reflected or transmitted, thereby reducing the manufacturing process and manufacturing cost, and creating a diffraction pattern of external light or reducing color separation of external light.

In addition, according to an embodiment, at least one of the opening of the pixel defining layer and the opening of the light blocking layer is formed in an oval or a similar shape, the angle of the major axis of the oval is arranged in various ways, the eccentricity of the oval is variously formed, or the oval is formed in a plurality of shapes. By having a merged structure that combines ellipses with eccentricity, color separation of external light can be reduced, or a constant diffraction pattern can be generated regardless of the angle.

According to embodiments, the diffraction pattern can be reduced by reducing the rate at which external light is reflected by using a black pixel defining layer instead of the polarizer to separate the light emitting layers from each other.

### BRIEF DESCRIPTION OF THE DRAWINGS

FIG. 1 is a schematic perspective view illustrating a usage state of a display device according to an embodiment.

FIG. 2 is an exploded perspective view of a display device according to an embodiment.

FIG. 3 is a schematic cross-sectional view of a display device according to an embodiment.

FIG. 4 is a block diagram of a display device according to an embodiment.

FIG. 5 is a perspective view schematically showing a light emitting display device according to an embodiment.

FIG. 6 is an enlarged plan view of a partial area of a light emitting display device according to an embodiment.

FIG. 7 is a schematic cross-sectional view of a display panel according to an embodiment.

FIG. 8 is a plan view of a portion of a display panel according to an embodiment.

FIG. 9 is a schematic cross-sectional view along a line IX-IX of the display panel of FIG. 8.

FIG. 10 is a schematic cross-sectional view along a line X-X of the display panel of FIG. 8.

FIG. 11 is a plan view illustrating color filters of a display area according to an embodiment.

FIG. 12 is a plan view of a portion of a display panel according to an embodiment.

FIG. 13 is a graph showing the transmittance according to the wavelength of the color filter.

FIG. 14 is a plan view of a portion of a display panel according to an embodiment.

FIG. 15 is a photograph capturing the reflection characteristics of external light for the embodiment of FIG. 14.

FIG. 16 is a plan view of a portion of a display panel according to a comparative example.

FIG. 17 is a photograph capturing the reflection characteristics of external light for the comparative example of FIG. 16.

FIG. 18 is a diagram explaining the principle of diffraction pattern occurring due to the reflection of external light.

FIG. 19 is a schematic cross-sectional view of a display panel according to an embodiment.

FIG. 20 is a table showing various embodiments.

FIG. 21 to FIG. 23 are plan views of a portion of a display panel according to an embodiment.

FIG. 24 and FIG. 25 are plan views of a portion of a display panel according to an embodiment.

FIG. 26 is a plan view of a portion of a display panel according to an embodiment.

FIG. 27 is a plan view showing the configuration of a unit pixel of one of the display panels according to an embodiment.

FIGS. 28 and 29 are diagrams showing a structure in which ellipses with different eccentricities are merged.

FIG. 30 is a cross-sectional view of a light emitting display device according to an embodiment.

FIG. 31 is a plan view of a portion of a display panel according to an embodiment.

FIG. 32 is a schematic cross-sectional view of a display panel according to an embodiment.

### DETAILED DESCRIPTION OF THE EMBODIMENTS

Hereinafter, with reference to the attached drawings, various embodiments of the present disclosure will be described in detail so that those skilled in the art can easily implement the present disclosure.

The present disclosure may be implemented in many different forms and is not limited to the embodiments described herein.

In order to clearly explain the present disclosure, parts that are not relevant to the description are omitted, and the same reference numerals are used for the same or similar components throughout the specification.

In addition, the size and thickness of each component shown in the drawings are arbitrarily shown for convenience of explanation, so the present disclosure is not necessarily limited to what is shown. In the drawing, the thickness is enlarged to clearly express various layers and areas. And in the drawings, for convenience of explanation, the thicknesses of some layers and regions are exaggerated.

Additionally, when a part, such as a layer, membrane, region, plate, or component is said as being “above” or “on” another part, it includes not only cases where it is directly “on” another part but also cases where another part is interposed therebetween.

In contrast, when an element is referred to as being “directly on” another element, there are no intervening elements present.

In addition, when a part is described as being “above” or “on” a reference part, it means that it is positioned above or below the reference part, and does not necessarily imply that it is positioned it in the direction opposite to gravity.

In addition, throughout the specification, when a part is said to “include” a certain component, it means that, unless specifically stated otherwise, other components may be included in addition to the specified component.

In addition, throughout the specification, when a part is referred to as being “on a plane,” it means viewing the target portion from above, and when a part is referred to as being “in a cross-section,” it means viewing the target portion, which is cut vertically, from the side.

Also, throughout the specification, when it is stated that components are “connected”, it not only means that two or more components are directly connected, but also includes cases where two or more components are indirectly connected through other components, are physically connected, or are electrically connected. Additionally, it can include cases where parts that are referred to by different names due to their position or function but are essentially integrated are connected to each other.

In addition, throughout the specification, when a portion such as a wire, layer, film, region, plate, or component is said to “extend in the first or second direction,” it does not only mean a straight shape extending in that direction. It also includes structures that generally extend in the first or second direction while bending at certain parts, having a zigzag structure, or including a curved structure.

In addition, electronic devices that include display devices, display panels, etc. described in the specification (for example, mobile phones, TVs, monitors, laptop computers, etc.) or electronic devices that include display devices, display panels, etc. manufactured by the manufacturing method described in the specification are not excluded from the scope of the claims of this specification.

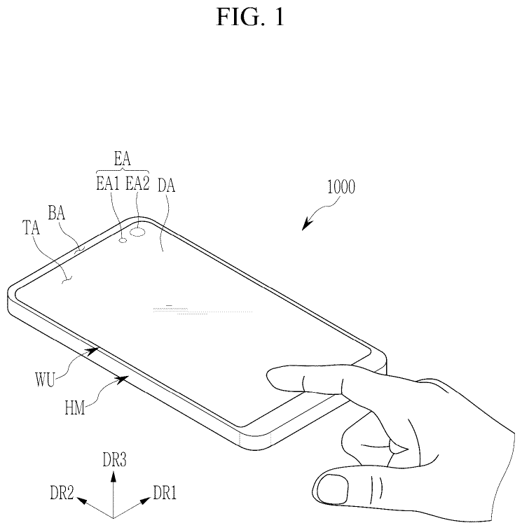

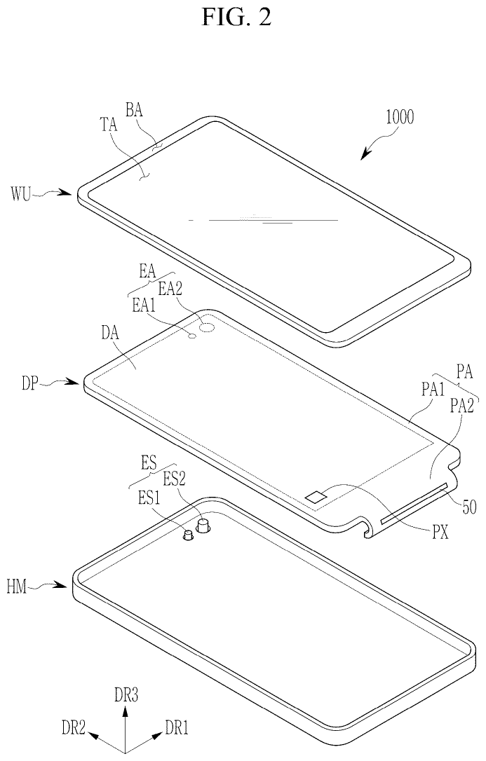

Below, we will briefly look at the structure of the display device through FIGS. 1 and 2.

FIG. 1 is a schematic perspective view showing a usage state of a display device according to an embodiment, and FIG. 2 is an exploded perspective view of a display device according to an embodiment.

Referring to FIG. 1, a display device 1000 according to an embodiment is a device that displays moving images or still images, and may be used in a mobile phone, a smart phone, a tablet personal computer, or a mobile phone. The display device 1000 is also used in portable electronic devices such as communication terminals, electronic notebooks, e-books, a PMP (portable multimedia player), navigation devices, a UMPC (Ultra Mobile PC), as well as televisions, laptops, monitors, billboards, internet of things (IOT), etc., and it can be used as a display screen for various products.

In addition, the display device 1000 according to an embodiment is mounted on a wearable device such as a smart watch, a watch phone, a glasses-type display, and a head mounted display HMD.

In addition, the display device 1000 according to an embodiment may be used as a dashboard of a car, a center information display CID placed on the center fascia or dashboard of a car, and a room mirror display (a display instead of a side mirror of a car), or may be used as rear-seat entertainment display placed on the back of the front seat.

FIG. 1 shows the display device 1000 being used as a smart phone for convenience of explanation.

The display device 1000 may display an image in a third direction DR3 on a display surface parallel to each of a first direction DR1 and a second direction DR2. The display surface on which the image is displayed may correspond to the front surface of the display device 1000 and the front surface of a cover window WU. Images can include static images as well as dynamic images.

In this embodiment, the front (or top) and back (or bottom) surfaces of each member are defined based on the direction in which the image is displayed. The front and back surfaces are opposed to each other in the third direction DR3, and the normal directions of each of the front and back surfaces may be parallel to the third direction DR3. The separation distance between the front and back surfaces in the third direction DR3 may correspond to the thickness of the display panel in the third direction DR3.

The display device 1000 according to an embodiment may detect a user's input (refer to the hand in FIG. 1) applied from the outside. The user's input may include various types of external inputs, such as parts of the user's body, light, heat, or pressure. In an embodiment, the user's input is shown with the user's hand applied to the front. However, the present disclosure is not limited to this. The user's input may be provided in various forms, and the display device 1000 may also detect the user's input applied to the side or back of the display device 1000 depending on the structure of the display device 1000.

Referring to FIGS. 1 and 2, the display device 1000 may include the cover window WU, a housing HM, a display panel DP, and an optical element ES. In an embodiment, the cover window WU and the housing HM may be combined to configure the exterior of the display device 1000.

The cover window WU may include an insulating panel. For example, the cover window WU may be made of glass, plastic, or a combination thereof.

The front of the cover window WU may define the front of the display device 1000. A transmission area TA may be an optically transparent area. For example, the transmission area TA may be an area with a visible light transmittance of about 90% or more.

A blocking area BA may define the shape of the transmission area TA. The blocking area BA is adjacent to the transmission area TA and may surround the transmission area TA. The blocking area BA may be an area with relatively low light transmittance compared to the transmission area TA. The blocking area BA may include an opaque material that blocks light. The blocking area BA may have a predetermined color. The blocking area BA may be defined by a bezel layer provided separately from the transparent substrate that defines the transmission area TA, or may be defined by an ink layer formed by inserting or coloring the transparent substrate.

The display panel DP may include a display pixel PX that displays an image and a driver 50, and the display pixel PX is located in a display area DA and the component area EA. The display panel DP may include a front surface that comprises a display area DA and a peripheral area PA. In an embodiment, the display area DA and the component area EA are areas including pixels where an image is displayed, and at the same time, a touch sensor is located above the pixels in the third direction DR3 to detect an external input.

The transmission area TA of the cover window WU may at least partially overlap the display area DA and the component area EA of the display panel DP. For example, the transmission area TA may overlap the front surface of the display area DA and the component area EA, or may overlap at least a portion of the display area DA and the component area EA. Accordingly, the user can view the image through the transmission area TA or provide external input based on the image. However, the present disclosure is not limited to this. For example, the area where an image is displayed and the area where external input is detected may be separated from each other.

The peripheral area PA of the display panel DP may at least partially overlap the blocking area BA of the cover window WU. The peripheral area PA may be an area covered by the blocking area BA. The peripheral area PA is adjacent to the display area DA and may surround the display area DA. An image is not displayed in the peripheral area PA, and a driving circuit or driving wiring for driving the display area DA may be disposed in the peripheral area PA. The peripheral area PA may include a first peripheral area PA1 located outside the display area DA and a second peripheral area PA2 which includes the driver 50, connection wiring, and a bending area. In the embodiment of FIG. 2, the first peripheral area PA1 is located on the three sides of the display area DA, and the second peripheral area PA2 is located on the remaining side of the display area DA.

In an embodiment, the display panel DP may be assembled in a flat state with the display area DA, component area EA, and peripheral area PA facing the cover window WU. However, the present disclosure is not limited to this. A portion of the peripheral area PA of the display panel DP may be bent. At this time, part of the peripheral area PA may be directed toward the back of the display device 1000, thereby reducing the blocking area BA visible on the front of the display device 1000. In FIG. 2, the second peripheral area PA2 can be bent and placed on the back of the display area DA and then assembled.

Additionally, the component area EA of the display panel DP may include a first component area EA1 and a second component area EA2. The first component area EA1 and the second component area EA2 may be at least partially surrounded by the display area DA. The first component area EA1 and the second component area EA2 are shown spaced apart from each other. However, the present disclosure is not limited thereto, and the first component area EA1 and the second component area EA2 may be at least partially connected. The first component area EA1 and the second component area EA2 may be areas in which an optical element (see ES in FIG. 2; hereinafter referred to as a component) that uses infrared rays, visible rays, or sound is disposed.

The display area (DA; hereinafter also referred to as the main display area) and the component area EA may include a plurality of light emitting diodes and a plurality of pixel circuit units. Each of the plurality of pixel circuit units may generate and transmit light-emitting current to each of the plurality of light emitting diodes. Here, a light emitting diode and a pixel circuit unit corresponding to the light emitting diode are called a pixel PX. The pixel circuit unit and the light emitting diode may correspond in a one-to-one manner in the display area DA and the component area EA.

The first component area EA1 may include a transparent portion through which light or sound can transmit and a display portion including a plurality of pixels. The transmission portion is located between adjacent pixels and is composed of a layer through which light and/or sound can transmit.

The transmission portion may be located between adjacent pixels, and depending on the embodiment, a layer that does not transmit light (e.g., visible light) of a specific wavelength may overlap with the first component area EA1. The number of pixels (hereinafter referred to as resolution) per unit area of the pixels (hereinafter referred to as normal pixels) included in the display area DA and the pixels included in the first component area EA1 (hereinafter referred to as first component pixels) may be the same.

The second component area EA2 includes a region composed of a transparent layer that allows light to pass through (also referred to as a light transmitting area). The light-transmitting area does not have a conductive layer or a semiconductor layer, which would block light. For example, a pixel defining layer or at least two color filters may include openings that ovelap with the second component area EA2, thus having a structure that does not block light. The number of pixels per unit area of the pixels included in the second component area EA2 (hereinafter also referred to as second component pixels) may be smaller than the number of pixels per unit area of the normal pixels included in the display area DA. As a result, the resolution of the second component pixel may be lower than that of the normal pixel.

The display panel DP may further include a touch sensor TS in addition to the display area DA that contains the display pixels PX. The display panel DP may be visible from the outside through the transmission area TA, including pixels PX, generate images. Additionally, the touch sensor TS may be disposed on top of the pixel PX and may detect an external input applied from outside. The touch sensor TS can detect an external input provided to the cover window WU.

Referring again to FIG. 2, the second peripheral area PA2 may include a bending portion. The display area DA and the first peripheral area PA1 may have a flat surface substantially parallel to the plane defined by the first direction DR1 and the second direction DR2, and one side of the second peripheral area PA2 extended from the flat surface may pass through a bending portion, and then may be in a flat state again. As a result, at least a portion of the second peripheral area PA2 may be bent and be disposed on the rear side of the display area DA. When assembled, at least a portion of the second peripheral area PA2 overlaps with the display area DA on a plane, thereby reducing the blocking area BA of the display device. However, the present disclosure is not limited to this. For example, the second peripheral area PA2 may not be bent.

The driver 50 may be mounted on the second peripheral area PA2, on the bending part, or located on at least one side of the bending part. The driver 50 may be provided in the form of a chip.

The driver 50 is electrically connected to the display area DA and the component area EA and can transmit electrical signals to pixels in the display area DA and the component area EA. For example, the driver 50 may provide data signals to the pixels PX arranged in the display area DA. The driver 50 may include a touch driving circuit and may be electrically connected to the touch sensor TS disposed on the display area DA and the component area EA. The driver 50 may include various circuits in addition to the above-described circuits or may be designed to provide various electrical signals to the display area DA.

The display device 1000 may include a pad portion located at an end of the second peripheral area PA2, and is electrically connected to a flexible printed circuit board FPCB which includes a driving chip through the pad portion. Here, the driving chip located on the flexible printed circuit board may include various driving circuits for driving the display device 1000 or a connector for supplying power. Depending on the embodiment, a rigid printed circuit board PCB may be used instead of the flexible printed circuit board.

The optical element ES may be disposed below the display panel DP. The optical element ES may include the first optical element ES1 overlapping the first component area EA1 and the second optical element ES2 overlapping the second component area EA2.

The first optical element ES1 may use infrared rays. The first component area EA1 may overlap with a layer that does not transmit light, such as a light blocking area of a color filter.

Depending on the embodiment, the first optical element ES1 may be replaced with an electronic element that uses light or sound. For example, instead of the first optical element ES1, it may be a sensor that receives and uses light such as an infrared sensor, a sensor that outputs and detects light or sound to measure distance or recognize a fingerprint, a small lamp that outputs light, or a speaker that outputs sound, etc.

In the case of electronic elements that use light, it is of course possible to use light of various wavelength bands, such as visible light, infrared light, and ultraviolet light.

The second optical element ES2 is at least one of a camera, an IR camera, a dot projector, an IR illuminator, and a Time-of-Flight sensor.

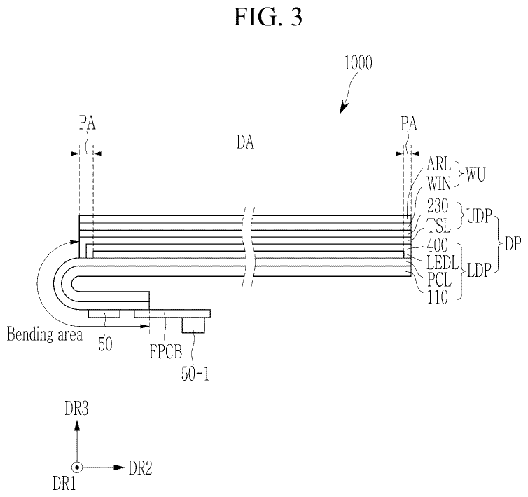

The light emitting display device described above may have a cross-sectional structure as shown in FIG. 3, and the cross-sectional structure will be examined through FIG. 3.

FIG. 3 is a schematic cross-sectional view of a display device according to an embodiment.

Referring to FIG. 3, the light emitting display device 1000 includes the display panel DP which is divided into a lower panel layer LDP and an upper panel layer UDP, and the cover window WU positioned on the front of the display panel.

The lower panel layer LDP of the display panel DP includes a light emitting device layer LEDL, which includes light emitting diodes constituting the pixel PX are located on a substrate 110, and a pixel circuit layer PCL, which transmits current to the light-emitting diodes in the light-emitting device layer LEDL. The pixel circuit layer PCL may be located between the substrate 110 and the light emitting device layer LEDL. The lower panel layer LDP further includes an encapsulation layer 400, and the light emitting device layer LEDL is covered by the encapsulation layer 400. Due to the encapsulation layer 400, the light emitting device layer LEDL can be protected from moisture and air from outside.

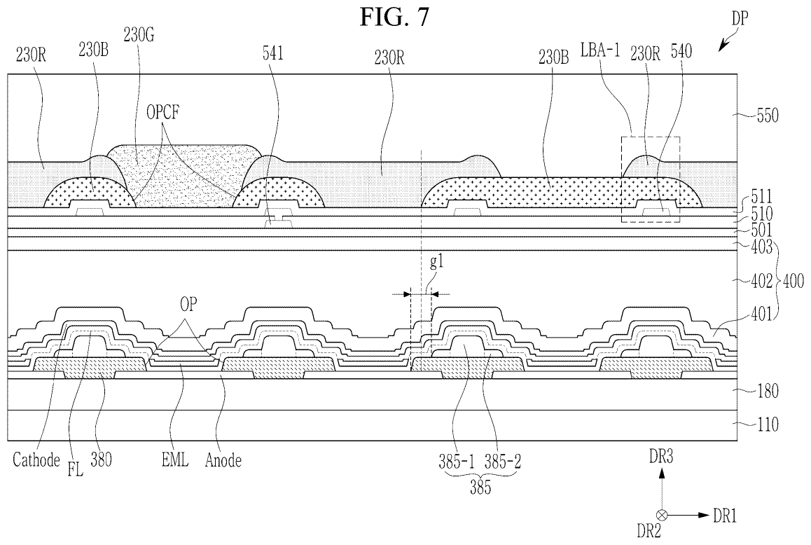

The upper panel layer UDP of the display panel DP may include a touch sensing layer TSL and a color filter layer 230. The touch sensing layer TSL may include a sensing insulating layer (refer to 501, 510, and 511 in FIG. 7) and a plurality of sensing electrodes (refer to 540 and 541 in FIG. 7). The color filter layer 230 may include a light blocking area of a color filter in which two or more color filters overlap.

Each structure of the display device will be described in detail as follows.

The substrate 110 is a base substrate or base member, and may be a flexible substrate capable of bending, folding, rolling, etc. For example, the substrate 110 may include a polymer resin such as polyimide PI. However, the present disclosure is not limited thereto. For example, the substrate 110 may include a glass material or a metal material.

The pixel circuit layer PCL may be disposed on the substrate 110. The pixel circuit layer PCL may include a plurality of thin film transistors constituting the pixel circuit unit of the pixel PX, and may additionally include a capacitor. The pixel circuit layer PCL may include wiring connected to the pixel circuit unit, such as a scan line, a data line, and a power voltage line. Each of the plurality of thin film transistors may include a semiconductor region, a source electrode, a drain electrode, and a gate electrode. The pixel circuit layer PCL may be located in the display area DA, and depending on the embodiment, it may also be located in a portion of the peripheral area PA or a portion of the bending area.

The light emitting device layer LEDL may be disposed on the pixel circuit layer PCL. The light emitting device layer LEDL may include a plurality of light emitting diodes including an anode, a cathode, and a light emitting layer that emit light, and a pixel defining layer that defines a light emitting area. A plurality of light emitting devices of the light emitting device layer LEDL may be disposed in the display area DA.

In an embodiment, the light emitting layer may be an organic light emitting layer containing an organic material. The light emitting didode may further include at least one functional layer such as an electron transport layer and a hole transport layer above and below the light emitting layer. When a current flows between the anode and the cathode, holes and electrons may move to the light emitting layer through the hole transport layer and electron transport layer, respectively, and may combine with each other in the light emitting layer to emit light.

Depending on the embodiment, the light emitting device may include a quantum dot light emitting diode including a quantum dot light emitting layer, an inorganic light emitting diode including an inorganic semiconductor, or a micro light emitting diode.

The encapsulation layer 400 may cover the top and side surfaces of the light emitting device layer LEDL and protect the light emitting device layer LEDL. The encapsulation layer 400 may include at least one inorganic layer and at least one organic layer to encapsulate the light emitting device layer LEDL.

The touch sensing layer TSL may be disposed on the encapsulation layer 400. The touch sensing layer TSL may include a plurality of sensing electrodes for detecting a user's touch in a capacitive manner, and a plurality of sensing lines connecting the plurality of sensing electrodes and the touch driver 50-1.

Depending on the embodiment, the touch sensing layer TSL may detect the user's touch using a mutual capacitance method or a self-capacitance method.

Depending on the embodiment, the touch sensing layer TSL may be formed on a separate substrate disposed on the light emitting device layer LEDL. In this case, the substrate supporting the touch sensing layer TSL may serve as an encapsulation substrate that encapsulates the light emitting device layer LEDL. When the encapsulation substrate is located, the encapsulation layer 400 may be omitted.

The plurality of sensing electrodes of the touch sensing layer TSL may not overlap with the light emitting area, and may be located to be covered by a light blocking area of a color filter, etc., which will be described later.

The color filter layer 230 is disposed on the touch sensing layer TSL and may include a light blocking area of the color filter which is formed with overlapping two or more color filters. The light blocking area of the color filter may cover the sensing electrode and may be positioned without overlapping with the light emitting area, and the color filter may enhance the color of light emitted from the light emitting diode by overlapping each color filter with the corresponding light emitting area.

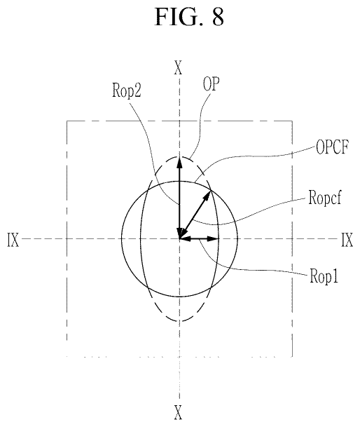

The color filter layer 230 may have a structure that reduces the reflection of external light so that external light flowing incident into the display device 1000 is not reflected again. This will be explained in more detail with reference to FIG. 8, etc.

The substrate 110 may have a structure folded toward the back of the display panel DP. The driver 50 is located on one side of the folded substrate 110, and electrically connects to a printed circuit board FPCB on which the touch driver 50-1 is attached.

The driver 50 may output signals and voltages for driving the display panel DP. The driver 50 supplies data voltages to a plurality of data lines, supplies respective power voltages to power lines such as driving voltage lines, and supplies control signals such as clock signals which generate scan signals to be applied to scan lines. The driver 50 may be formed of an integrated circuit IC and mounted on the display panel DP using a chip on glass COG method, a chip on plastic COP method, or an ultrasonic bonding method. For example, the driver 50 may be positioned on an opposite surface to the display area DA in the third direction DR3 by bending the substrate 110, and may be positioned on the back of the display area DA. Depending on the embodiment, the driver 50 may be mounted on a circuit board FPCB.

The circuit board FPCB may be attached to the pad portion of the display panel DP using an anisotropic conductive film ACF. The pad portion of the circuit board FPCB may be electrically connected to the pad portion of the display panel DP. The circuit board FPCB may be a flexible printed circuit board, a printed circuit board, or a flexible film such as a chip on film.

The touch driver 50-1 may be mounted on a circuit board FPCB. The touch driver 50-1 is electrically connected to the sensing electrode of the touch sensing layer TSL in the display panel DP, and may supply a drive signal to a plurality of sensing electrodes, and detect changes in the electrostatic capacity between the plurality of sensing electrodes to determine whether there is a touch. The touch driver 50-1 may be formed of an integrated circuit IC.

The cover window WU is disposed on the front of the display panel DP, and the cover window WU may include a window WIN and an anti-reflection layer ARL.

The window WIN may be disposed on the color filter layer 230 and may be attached to the color filter layer 230 using a transparent adhesive. The window WIN may serve to protect the display panel DP. A window WIN may be made of a transparent material. The window WIN may include, for example, glass or plastic.

When the window WIN includes glass, the glass may be ultra-thin glass UTG or thin-film glass. Ultra-thin glass can be strengthened to have a predetermined stress profile internally. The strengthened ultra-thin glass is better at preventing cracks, crack propagation, and breaking due to external impacts compared to before strengthening. Through the strengthening process, the ultra-thin glass strengthened may have varying stresses in different regions.

When glass is made of an ultra-thin film or thin film, it has flexible characteristics and can be bent, folded, or rolled. The thickness of the glass may range from, for example, 10 μm to 300 μm, and specifically, glass with a thickness of 10 μm to 100 μm or about 50 μm may be applied. The glass of the window WIN may include soda lime glass, alkali aluminosilicate glass, borosilicate glass, or lithium aluminasilicate glass. The glass of a window WIN may include chemically strengthened or thermally strengthened glass to have strong strength. Chemical strengthening may be achieved through an ion exchange treatment process in alkaline salts. The ion exchange treatment process may be performed two or more times. Additionally, the window WIN may be a polymer film coated with a thin glass on both sides.

An anti-reflection layer ARL may be disposed on the front of the window WIN, and the anti-reflection layer ARL may be attached to the front of the window WIN in the form of an optical film.

The anti-reflection layer ARL may be disposed on the window WIN. The anti-reflection layer ARL may protect the window WIN and reduce the reflection of external light.

The anti-reflection layer ARL may include a hard coating layer and a low refractive index layer. Due to two layers with different refractive indices, the anti-reflection layer ARL may cause external light to be lost or undergo destructive interference at the interface, and may prevent or reduce the reflection of external light. The low refractive index layer may have a structure including particles dispersed in a transparent resin. Depending on the embodiment, a high refractive index layer may be additionally included, and the high refractive index layer may be positioned between the hard coating layer and the low refractive index layer.

The hard coating layer, low refractive index layer, and high refractive index layer that may be included in the anti-reflection layer ARL may have the following characteristics.

The hard coating layer may reduce distortion or lifting of the anti-reflection layer ARL under harsh conditions such as high temperature and high humidity, thereby improving reliability problems.

The hard coating layer may include an organic layer. The organic layer may be at least one of an acrylate-based compound, a urethane-based compound, polyimide, polycarbonate, polyethersulfone, polyethylene naphthalate, polyphenylene sulfide, LCP (liquid crystal polymer), polymethyl methacrylate, and an epoxy polymer, or it may include a combination thereof.

In an embodiment, the hard coating layer may include an organic layer and an organic-inorganic composite layer. In this case, the organic layer may include an acrylate-based compound. For example, the organic layer may be formed including urethane acrylate. The organic layer may serve as a stress buffer layer.

The organic material in the organic-inorganic composite layer may be formed from at least one of an acrylate-based compound, a polyurethane-based compound, or an epoxy-based compound, or a combination thereof. For example, the organic material may include urethane acrylate. Among the organic-inorganic composite layers, the inorganic material is at least one selected from the group consisting of silicon oxide (SiO₂), zirconium oxide (ZrO₂), aluminum oxide (Al₂O₃), tantalum oxide (Ta₂O₅), niobium oxide (Nb₂O₅ or NbO₂), and glass beads.

The inorganic material may be provided in the form of a single type of inorganic oxide listed above or a mixture thereof. Additionally, inorganic materials may be provided in various forms to form an organic-inorganic composite layer. For example, silicon oxide can be provided in the form of particles, sol, or having a hollow shape.

In the organic-inorganic composite layer, the organic acrylate compound and the inorganic particles may be mixed at a weight ratio of 5:5 to 8:2. By containing both an acrylate compound and inorganic particles, the organic-inorganic composite layer improves surface hardness and has shock absorbency against external shock, forming a hard coating layer that is not easily broken.

In an embodiment, the hard coating layer may include an acrylate-based compound and a urethane-based compound. Acrylate-based compounds and urethane-based compounds may be mixed and polymerized in monomer form. Acrylate-based compounds may increase the hardness of the low refractive index layer, thereby enhancing the hardness and wear resistance of the anti-reflection layer ARL. The urethane-based compound may increase the elasticity of the anti-reflection layer ARL by providing flexibility to the low refractive index layer. In this case, the proportion of the acrylate-based compound in the hard coating layer may be 70% to 99.9%, and the proportion of the urethane-based compound may be 0.1% to 30%. For example, the mixing ratio of the acrylate-based compound and the urethane-based compound may be 7:3 or more, and the ratio of the acrylate-based compound may be further increased. For example, the mixing ratio of the acrylate-based compound and the urethane-based compound may be further increased, such as 7:3, 8:2, or 9:1.

In an embodiment, the hard coating layer may include an acrylate-based compound. In this case, the acrylate-based compound may be an acrylic resin. That is, the hard coating layer can improve the hardness and wear resistance of the anti-reflection layer ARL by including acrylic resin.

The thickness of the hard coating layer may be 2 μm to 10 μm. By having the hard coating layer within the above thickness range, distortion or lifting phenomena may be reduced and reliability problems may be improved.

The refractive index of the hard coating layer may be 1.48 to 1.53. By having the hard coating layer in the above refractive index range, it has a difference in refractive index at the interface with the low refractive index layer, which will be described later, and refracts the light emitted from the light emitting device layer upward to increase light output efficiency and reduce reflection of external light.

The low refractive index layer may be disposed on the hard coating layer. The low refractive layer can refract light emitted from the light emitting device layer upward to increase the output efficiency of light and reduce the reflection of external light.

The low refractive index layer may include particles dispersed in a transparent resin.

Resins may include one or more selected from the group consisting of acryl, polysiloxane, polyurethane, polyurethane acrylate, polyimide, PMSSQ (polymethylsilsesquioxane), and PMMA (poly (methyl methacrylate)).

The particles may be hollow particles. For example, the particles may include one or more selected from the group consisting of silica (SiO₂), magnesium fluoride (MgF₂), and iron oxide (Fe₃O₄). Additionally, the particle may include a shell made of one or more of the above materials and a hollow interior of the shell. In an embodiment, the diameter of the particle may be 10 to 200 nm, and the thickness of the shell and the diameter of the hollow may be determined depending on the diameter of the particle.

Particles included in the low refractive index layer may be in a weight ratio of 10% to 50% relative to the resin. If the weight ratio of particles to resin is 10% or more, the refractive index of the low refractive index layer may be lowered, and if it is 50% or less, adhesion to adjacent layers may be prevented from being reduced. The low refractive index layer can be formed by coating and curing a solution containing a solvent in which resin and particles are dispersed.

The thickness of the low refractive layer may be 10 to 200 nm. By having the low refractive index layer within the above thickness range, it may contain sufficient particles to lower the refractive index and improve adhesion to the lower layer.

The refractive index of the low refractive index layer may be smaller than the refractive index of the hard coating layer. For example, the refractive index of the low refractive index layer may be 0.05 or smaller than the refractive index of the hard coating layer. If the difference between the refractive index of the low refractive index layer and the hard coating layer is 0.05 or more, total reflection of external light may be increased at the interface between the low refractive index layer and the hard coating layer, leading to destructive interference with light reflected from the surface of the low refractive index layer. Accordingly, the reflectance of external light of the anti-reflection layer ARL can be reduced. The refractive index of the low refractive layer may range from 1.3 to 1.43. However, the present disclosure is not limited to this, and a lower refractive index may be used within a range smaller than the refractive index of the hard coating layer.

The high refractive index layer may include an inorganic material, an organic material, or an inorganic material and an organic material. Therefore, the high refractive index layer may be made of an inorganic film, an organic film, or an organic film containing inorganic particles.

Inorganic substances contained in the high refractive index layer include zinc oxide, titanium oxide, zirconium oxide, niobium oxide, tantalum oxide, and tin oxide, and may be one or more selected from nickel oxide, silicon oxide, silicon nitride, indium nitride, and gallium nitride.

The organic material included in the curved layer may be one or more selected from poly(3,4-ethylenedioxythiophene) (PEDOT), 4,4′-bis[N-(3-methylphenyl)-N-phenylamino]biphenyl (TPD), 4,4′, 4″-tris[(3-methylphenyl)phenylaminotriphenylamine (m-MTDATA), 1,3,5-tris[N,N-bis(2-methylphenyl)-amino]-benzene (o-MTDAB), 1,3,5-tris[N,N-bis(3-methylphenyl)-amino]-benzene (m-MTDAB), 1,3,5-tris[N,N-bis(4-methylphenyl)-amino]-benzene (p-MTDAB), 4,4′-bis[N,N-bis(3-methylphenyl)-amino]-diphenylmethane (BPPM), 4,4′-dicarbazolyl-1,1′-biphenyl (CBP), 4,4′, 4″-iris (N-carbazole)triphenylamine (TCTA), 2,2′, 2″-(1,3,5-benzentolyl)tris-[1-phenyl-1H-benzimidazole] (TPBI), and 3-(4-biphenyl)-4-phenyl-5-t-butylphenyl-1,2,4-triazole (TAZ).

The refractive index of the high refractive index layer may be greater than that of the low refractive index layer to reduce reflection of external light. For example, the refractive index of the high refractive index layer may be 0.05 or more than the refractive index of the low refractive index layer. The refractive index of the high refractive index layer may range from 1.53 to 1.7. However, the present disclosure is not limited to this, and a larger refractive index may be used within a range larger than that of the low refractive index layer.

The thickness of the high refractive index layer may be 50 to 200 nm. By having the high refractive index layer within the above thickness range, the interface with the low refractive index layer may be formed flat and the bonding strength with the hard coating layer can be prevented from decreasing.

The anti-reflection layer ARL including a high refractive index layer can further reduce the reflection of external light by increasing the difference in refractive index at the interface with the low refractive index layer.

Depending on the embodiment, an optical film other than the anti-reflection layer ARL may be further included on the front surface of the window WIN, and an anti-fingerprint layer may be included. However, it does not include a polarizer because the color filter layer 230, which will be described later, lowers the reflectance of external light and makes it difficult for the user to see. Accordingly, depending on the embodiment, the anti-reflection layer ARL may not be included on the front surface of the window WIN.

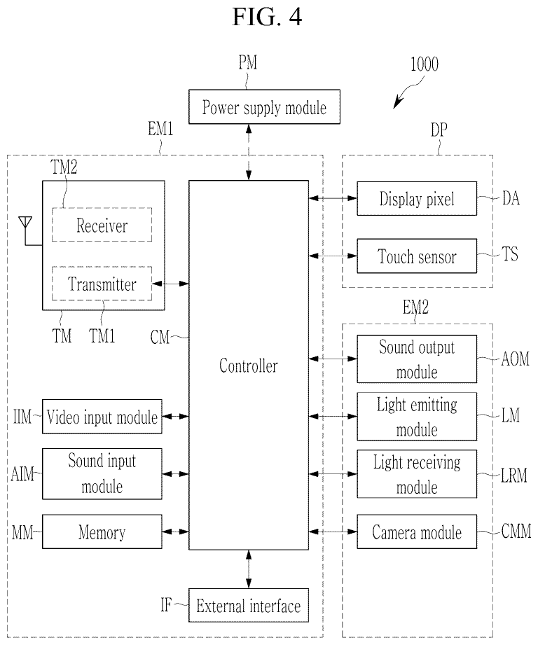

Hereinafter, a display device according to an embodiment will be described with reference to FIG. 4.

FIG. 4 is a block diagram of a display device according to an embodiment.

Referring to FIG. 4, the display device 1000 may include the display panel DP, a power supply module PM, a first electronic module EM1, and a second electronic module EM2. The display panel DP, the power supply module PM, the first electronic module EM1, and the second electronic module EM2 may be electrically connected to each other. In FIG. 4, a display pixel and a touch sensor TS located in the display area DA of the display panel DP are shown as an example.

A power supply module PM can supply power required for the overall operation of the display device 1000. The power supply module PM may include a conventional battery module.

The first electronic module EM1 and the second electronic module EM2 may include various functional modules for operating the display device 1000.

The first electronic module EM1 may be mounted directly on the motherboard electrically connected to the display panel DP, or may be mounted on a separate board and electrically connected to the motherboard through a connector (not shown).

The first electronic module EM1 may include a control module CM, a wireless communication module TM, an image input module IIM, an audio input module AIM, a memory MM, and an external interface IF. Some of the modules may not be mounted on the motherboard, but may be electrically connected to the motherboard through a flexible printed circuit board connected thereto.

The control module CM may control the overall operation of the display device 1000. The control module CM may be a microprocessor. For example, the control module CM activates or deactivates the display panel DP. The control module CM may control other modules, such as the image input module IIM or the audio input module AIM, based on the touch signal received from the display panel DP.

The wireless communication module TM may transmit/receive wireless signals to and from other terminals using a Bluetooth or Wi-Fi line. The wireless communication module TM may transmit/receive voice signals using a general communication line. The wireless communication module TM includes a transmitter TM1 that modulates and transmits a signal to be transmitted, and a receiver TM2 that demodulates the received signal.

The image input module IIM may process video signals and convert them into video data that can be displayed on the display panel DP.

The audio input module AIM may receive external audio signals through a microphone in recording mode, voice recognition mode, etc. and convert them into electrical voice data.

The external interface IF may serve as an interface connected to an external charger, wired/wireless data port, card socket (e.g., memory card, SIM/UIM card), etc.

The second electronic module EM2 may include an audio output module AOM, a light emitting module LM, a light receiving module LRM, and a camera module CMM, at least some of which include optical elements ES disposed on the back of the display panel DP, as shown in FIGS. 1 and 2. The optical element ES may include the light emitting module LM, the light receiving module LRM, and a camera module CMM. In addition, the second electronic module EM2 may be mounted directly on the motherboard or may be mounted on a separate board. The second electronic module EM2 may be connected to the display panel DP through a connector (not shown) or may be connected to the first electronic module EM1.

The audio output module AOM may convert audio data received from the wireless communication module TM or audio data stored in the memory MM, and output the converted audio data to the outside.

The light emitting module LM may generate and output light. The light emitting module LM may output infrared rays. For example, the light emitting module LM may include an LED device. For example, the light receiving module LRM may detect infrared light. The light receiving module LRM may be activated when infrared rays above a certain level are detected. The light receiving module LRM may include a CMOS sensor.

After the infrared light generated in the light emitting module LM is output, it is reflected by an external subject (e.g., a user's finger or face), and the reflected infrared light may be incident on the light receiving module LRM. The camera module CMM may capture external images.

In an embodiment, the optical element ES may additionally include a light detection sensor or a heat detection sensor. The optical element ES may detect an external subject received through the front or provide a sound signal such as voice to the outside through the front. Additionally, the optical element ES may include a plurality of components and is not limited to any one embodiment.

Referring to FIG. 2 again, the housing HM may be combined with the cover window WU. The cover window WU may be disposed on the front of the housing HM. The housing HM may be combined with the cover window WU to provide a predetermined accommodation space. The display panel DP and the optical element ES may be accommodated in a predetermined accommodation space provided between the housing HM and the cover window WU.

The housing HM may include a material with relatively high rigidity. For example, the housing HM may include a plurality of frames or plates made of glass, plastic, or metal, or a combination thereof. The housing HM may stably protect the components of the display device 1000 accommodated in the internal space from external shock.

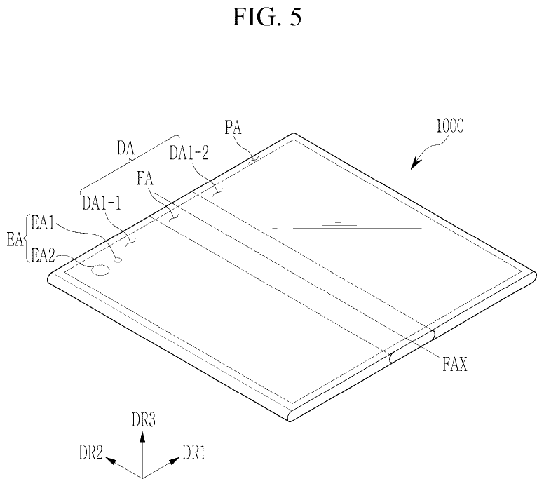

Hereinafter, the structure of the display device 1000 according to an embodiment will be described in detail with reference to FIG. 5.

FIG. 5 is a perspective view schematically showing a light emitting display device according to an embodiment.

Descriptions of the same components as those described above will be omitted, and the embodiment of FIG. 5 shows a foldable display device in which the display device 1000 is folded through a folding axis FAX.

Referring to FIG. 5, in an embodiment, the display device 1000 may be a foldable display device. The display device 1000 may be folded outward or inward based on the folding axis FAX. When the display device 1000 is folded outward based on the folding axis FAX, the display surfaces of the display device 1000 are positioned on the outside in the third direction DR3 so that images can be displayed in both directions. If the display device 1000 is folded inward based on the folding axis FAX, the display surface may not be visible from the outside.

In an embodiment, the display device 1000 may include a display area DA, a component area EA, and a peripheral area PA. The display area DA may be divided into a 1-1 display area DA1-1, a 1-2 display area DA1-2, and a folding area FA. The 1-1 display area DA1-1 and the 1-2 display area DA1-2 may be located on the left and right sides, respectively, based on (or centered on) the folding axis FAX, and the first the folding area FA may be located between the 1-1 display area DA1-1 and the 1-2 display area DA1-2. When the display device 1000 is folded outward based on the folding axis FAX, the 1-1 display area DA1-1 and the 1-2 display area DA1-2 are located on both sides in the third direction DR3, and the display device 1000 displays images in both directions. Additionally, when the display device 1000 is folded inward based on the folding axis FAX, the 1-1st display area DA1-1 and the 1-2nd display area DA1-2 may not be visible from the outside.

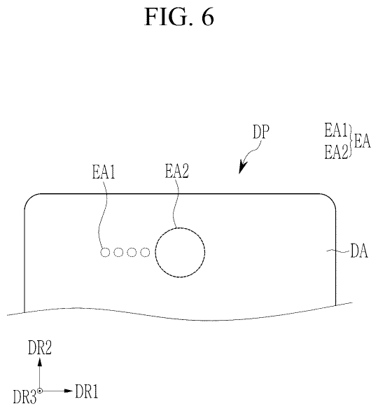

FIG. 6 is an enlarged plan view of a partial area of a light emitting display device according to an embodiment.

FIG. 6 shows a portion of a light emitting display panel DP of a light emitting display device according to an embodiment, and is shown using a display panel for a mobile phone.

The display area DA is located on the front of the light emitting display panel DP, and a component area EA is also located within the display area DA. Specifically, the component area EA may include the first component area EA1 and the second component area EA2. Additionally, in FIG. 6, the first component area EA1 is located adjacent to the second component area EA2. In FIG. 6, the first component area EA1 is located to the left of the second component area EA2. The location and number of first component areas EA1 may vary depending on the embodiment. In FIG. 6, the second optical element ES2 disposed in the second component area EA2 may be a camera, and the first optical element ES1 disposed in may be an optical sensor.

The display area DA may include a plurality of light emitting diodes and a plurality of pixel circuit units that generate and transmit light-emitting current to each of the plurality of light emitting diodes. Here, one light emitting diode and one pixel circuit unit connected to the light emitting diode are called a pixel PX. In the display area DA, one pixel circuit unit and one light emitting diode are formed in a one-to-one arrangement. The display area DA is hereinafter also referred to as the ‘normal display area’. Although the structure of the light emitting display panel DP below the cutting line is not shown in FIG. 6, the display area DA may be located below the cutting line.

The light emitting display panel DP according to the embodiment may be divided into a lower panel layer and an upper panel layer. The lower panel layer is a part where the light emitting diode and the pixel circuit unit that make up the pixel are located, and may even include an encapsulation layer (see 400 in FIG. 7) covering them. That is, the lower panel layer may include an anode, a pixel defining layer (see 380 in FIG. 7), a light emitting layer (see EML in FIG. 7), and a spacer (see 385 in FIG. 7) from the substrate (see 110 in FIG. 7) to the encapsulation layer, and it also includes a functional layer (see FL in FIG. 7), a cathode (see Cathode in FIG. 7), an insulating layer between the substrate and anode, a semiconductor layer, and a conductive layer. The upper panel layer is a part located above the encapsulation layer and includes a sensing insulating layer capable of detecting touch (see 501, 510, and 511 in FIG. 7) and a plurality of sensing electrodes (see 540 and 541 in FIG. 7), and it may include a color filter (see 230 in FIG. 7), a planarization layer (see 550 in FIG. 7), etc.

The first component area EA1 may include only transparent layers that allow light to pass through and may not have a conductive layer or semiconductor layer. The lower panel layer may have a light sensor. The upper panel layer may include a light blocking area, where the pixel defining layer and two or more color filters of the upper panel layer are overlapped, which includes an opening (hereinafter also referred to as an additional opening) corresponding to the first component area EA1. This structure allows light to pass through without obstruction. When the optical sensor area is located in the lower panel layer and there is no corresponding opening in the upper panel layer, it may be the display area DA rather than the first component area EA1. One first component area EA1 may include a plurality of adjacent optical sensor areas, and in this case, pixels adjacent to the optical sensor area may be included in the first component area EA1. When the first optical element ES1 corresponding to the first component area EA1 uses infrared light rather than visible light, the first component area EA1 may overlap with the light blocking area of the color filter that blocks visible light.

The second component area EA2 may include a second component pixel and a light transmission area, and the space between adjacent second component pixels may be a light transmission area.

Although not shown in FIG. 6, a peripheral area may be further located outside the display area DA. In addition, although FIG. 6 shows a display panel for a mobile phone, this embodiment may be applied to any display panel that accommodates an optical element on its back side, and it may also be a flexible display device.

In the case of a foldable display device among flexible display devices, the second component area EA2 and the first component area EA1 may be formed in different positions from those shown in FIG. 6.

Hereinafter, the structure of the light emitting display panel DP according to an embodiment will be described in detail with reference to FIG. 7.

FIG. 7 is a schematic cross-sectional view of a display panel according to an embodiment.

The light emitting display panel DP according to an embodiment may display an image by forming a light emitting diode on the substrate 110, may detect a touch by including a plurality of sensing electrodes 540 and 541, and, by including color filters 230R, 230G, 230B, the light emitted from the light emitting didode will also have the color characteristics of the color filters 230R, 230G, 230B. A black light blocking layer that blocks visible light may not be formed, and instead of a light blocking layer, at least two color filters may be overlapped to block visible light.

The area where at least two color filters are overlapped to block visible light is called the light blocking area of the color filter. In an embodiment of FIG. 7, a blue color filter 230B, the red color filter 230R, and a green color filter 230G are stacked sequentially. The order in which color filters are stacked may vary depending on the embodiment.

In addition, a polarizer may not be formed on the front surface of the light emitting display panel DP according to an embodiment. Instead, a pixel defining layer 380 is formed using a black organic material. By forming the light blocking area of the color filters, in which at least two or more color filters are overlap, on the top of the pixel defining layer 380, it is possible to prevent external light from being reflected from an anode or the like and reaching the user even if external light enters the interior.

A detailed look at the light emitting display panel DP according to an embodiment is as follows.

The substrate 110 may either include rigid materials, such as glass, that do not bend, or flexible materials that can bend, such as plastic or polyimide.

A plurality of thin film transistors is formed on the substrate 110, but they are omitted in FIG. 7 and only the organic layer 180 covering the thin film transistors is shown. One pixel is formed with a light-emitting diode and a pixel circuit unit in which a plurality of transistors and capacitors that transmit light-emitting current to the light-emitting diode are formed.

In FIG. 7, the pixel circuit unit is not shown, and the structure of the pixel circuit unit may vary depending on the embodiment. In FIG. 7, the organic layer 180 covering the pixel circuit portion is shown first for convenience of explanation.

A light emitting diode including an anode, a light emitting layer EML, and a cathode is disposed on the organic layer 180.

An anode may include a single layer containing a transparent conductive oxide layer and a metal material, or multiple layers containing these. The transparent conductive oxide layer may include ITO (indium tin oxide), poly-ITO, IZO (indium zinc oxide), IGZO (indium gallium zinc oxide), or ITZO (indium tin zinc oxide), and the metal material may include silver (Ag), molybdenum (Mo), copper (Cu), gold (Au), and aluminum (Al).

The light emitting layer EML may include an organic light emitting material, and adjacent light emitting layers EML may display different colors. Depending on the embodiment, each light emitting layer EML may display light of the same color due to the color filters 230R, 230G, 230B disposed on the light emitting layers. Depending on the embodiment, the light emitting layer EML may have a structure in which a plurality of light emitting layers are stacked (also called a tandem structure).

The pixel defining layer 380 is disposed on the organic layer 180 and the anode. The pixel defining layer 380 has an opening (OP; hereinafter referred to as a first opening) which extends to the anode. The light emitting layer EML overlaps with a portion of and is disposed on the anode exposed by the opening OP. The light emitting layer EML is located only within the opening OP of the pixel defining layer 380 and is separated from the adjacent light emitting layer EML by the pixel defining layer 380.

The pixel defining layer 380 may include a negative type of black organic material. The black organic material may include a light blocking material, and the light blocking material may include carbon black, carbon nanotubes, a resin or paste containing black dye, metal particles such as nickel, aluminum, molybdenum, and alloys thereof, metal oxide particles (e.g., chromium nitride), and the like. The pixel defining layer 380 contains a light blocking material and is black in color, and may prevent the reflection of light by absorbing or blocking light rather than reflecting it. As the negative type of the organic material is used, the portion covered by a mask may be removed.

A spacer 385 may be formed on the pixel defining layer 380. The spacer 385 includes a first part 385-1 that is tall and located in a narrow area, and a second part 385-2 that is low in height and is located in a wide area. In FIG. 7, the first part 385-1 and the second part 385-2 are shown separated by a dotted line within the spacer 385. The first part 385-1 may serve to secure rigidity against pressing pressure by enhancing scratch strength. The second part 385-2 may serve to assist contact between the pixel defining layer 380 and the upper functional layer FL. The first part 385-1 and the second part 385-2 may include the same material, and may include a positive type of photosensitive organic material. For example, the first part 385-1 and the second part 385-2 may include photosensitive polyimide PSPI. As the positive type of the organic material is used, the portion not covered by the mask may be removed. The spacer 385 is transparent so that light may be transmitted or reflected.

While the pixel defining layer 380 may be formed using a negative type material and the spacer 385 may be formed using a positive type material, the pixel defining layer 380 and the spacer 385 may include the same materials depending on the embodiment.

At least a portion of the upper surface of the pixel defining layer 380 is covered by the spacer 385, and the edge of the second part 385-2 is spaced apart from the edge of the pixel defining layer 380. A portion of the pixel defining layer 380 is not covered by the spacer 385. The second part 385-2 covers even the upper surface of the pixel defining layer 380 where the first part 385-1 is not located, thereby strengthening the adhesion characteristics between the pixel defining layer 380 and the functional layer FL. In an embodiment, the spacer 385 is positioned only in an area that overlaps with the light blocking area of the color filter, where at least two color filters are stacked to block visible light. When viewed from the front of the display panel DP, the spacer 385 may not be visible because the spacer 385 is hidden by the light blocking area of the color filter.

A functional layer FL is disposed on the spacer 385 and the pixel defining layer 380. The functional layer FL may be disposed on the entire surface of the light emitting display panel DP or only in specific areas. For example, the functional layer FL may be formed on all areas except the light transmitting area of the second component area EA2. The functional layer FL may include an electron injection layer, an electron transport layer, a hole transport layer, and a hole injection layer, and the functional layer FL may be disposed above and below the light emitting layer EML. That is, the hole injection layer, hole transport layer, the light emitting layer EML, the electron transport layer, the electron injection layer, and the cathode are stacked sequentially on the anode. The hole injection layer and hole transport in the functional layer FL may be disposed below the light emitting layer EML, and the electron transport layer and the electron injection layer may be disposed on the light emitting layer EML.

The spacer 385 may enhance the scratch resistance of the light emitting display panel DP such that the spacer 385 may reduce the defect rate caused by pressing pressure. The spacer 385 may increase the adhesion to the functional layer FL disposed on the spacer 385, thereby preventing moisture and air from penetrating from the outside. In addition, high adhesive strength is advantageous in eliminating the problem of poor adhesion between layers when the light emitting display panel DP has flexible characteristics and is repeatedly folded and unfolded.

The cathode may include a light-transmitting electrode or a reflective electrode. Depending on the embodiment, the cathode may be a transparent or translucent electrode, and may include a metal thin layer having a small work function such as lithium (Li), calcium (Ca), lithium/calcium fluoride (LiF/Ca), lithium/aluminum fluoride (LiF/Al), aluminum (Al), silver (Ag), magnesium (Mg), and their compounds. Additionally, a transparent conductive oxide (TCO) layer, such as indium tin oxide (ITO), indium zinc oxide (IZO), zinc oxide (ZnO), or indium oxide (In₂O₃), may be further disposed on the metal thin layer. The cathode may be formed integrally over the entire surface of the light emitting display panel DP.

The encapsulation layer 400 is disposed on the cathode. The encapsulation layer 400 may include at least one inorganic layer and at least one organic layer. For example, as depicted in FIG. 7, the encapsulation layer 400 may be formed of a triple layer structure including the first inorganic encapsulation layer 401, the organic encapsulation layer 402, and the second inorganic encapsulation layer 403. The encapsulation layer 400 may be used to protect the light emitting layer EML including an organic material from moisture or oxygen that may pentrate from the outside. Depending on the embodiment, the encapsulation layer 400 may include a structure in which an inorganic layer and an organic layer are further sequentially stacked.

Sensing insulating layers 501, 510, 511 and a plurality of sensing electrodes 540, 541 are disposed on the encapsulation layer 400 for touch detection. In the embodiment of FIG. 7, touch is detected in a capacitive type using two sensing electrodes 540 and 541. However, depending on the embodiment, touch may be detected in a self-capacitive type using only one sensing electrode.

The plurality of sensing electrodes 540 and 541 may be insulated with a second sensing insulating layer 510 interposed therebetween. A lower sensing electrode 541 is disposed on the first sensing insulating layer 501, and the second sensing insulating layer 510 is interposed between the plurality of sensing electrodes 540 and 541. An upper sensing electrode 540 is disposed on the second sensing insulation layer 510, and the upper sensing electrode 540 is covered by a third sensing insulating layer 511. The plurality of sensing electrodes 540 and 541 may be electrically connected through an opening located in the second sensing insulating layer 510.

Here, the sensing electrodes 540 and 541 may include metal or metal alloy such as aluminum (Al), copper (Cu), silver (Ag), gold (Au), molybdenum (Mo), titanium (Ti), and tantalum (Ta), and may include a single layer or multiple layers.

Color filters 230R, 230G, 230B are disposed on the third sensing insulating layer 511. The color filters 230R, 230G, 230B may include a red color filter 230R that allows red light to pass through, the green color filter 230G that allows green light to pass through, and the blue color filter 230B that allows blue light to pass through. Each of the color filters 230R, 230G, 230B may be positioned to overlap the anode of the light emitting diode on a plane. Since the light emitted from the light emitting layer EML may change to a corresponding color as it passes through a color filter, all light emitted from the light emitting layer EML may have the same color. The light emitting layer EML may emit light of different colors, and the quality of the displayed color may be enhanced by passing through a corresponding color filter of the same color.

Depending on the embodiment, the color filters 230R, 230G, 230B may be replaced with a color conversion layer or may further include a color conversion layer. The color conversion layer may include quantum dots.

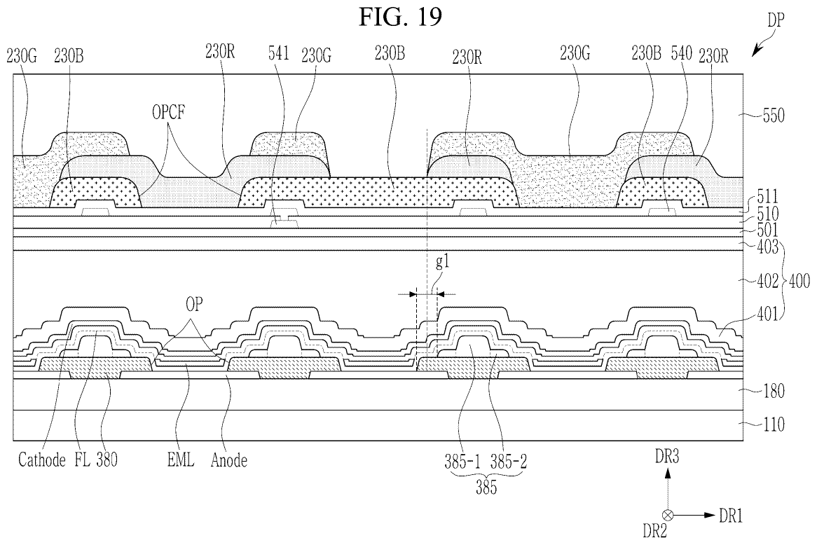

In the embodiment of FIG. 7, the black light blocking layer that blocks visible light is not formed, and a light blocking area of a color filter where at least two color filters are overlapped is formed instead of the light blocking layer. In the embodiment of FIG. 7, the light blocking area of the color filter is formed by sequentially stacking the blue color filter 230B and the red color filter 230R. The green color filter 230G overlaps only a portion of the light blocking area of the color filter, and does not constitute the light blocking area for the color filter. However, depending on the embodiment, the green color filter 230G may also overlap the entire area with the light blocking area of the color filter to form a light blocking area of the color filter (see FIG. 19). The order in which color filters are stacked may vary depending on the embodiment.

The light blocking area of a color filter in which at least two color filters are overlapped may be positioned to overlap with the sensing electrodes 540, 541 on a plane, and may be positioned not to overlap with at least a part of the anode and the light emitting layer EML on a plane.

This is to ensure that the anode and the light emitting layer EML capable of displaying an image are not obscured by the light blocking area of the color filter and the sensing electrodes 540 and 541.

In an area of the color filter other than the light blocking area, only a single color filter may be positioned. As light of the corresponding color passes through the single color filter, a light transmitting area of the color filter may be formed in that area. Hereinafter, the light transmitting area of the color filter where only the single color filter is disposed is referred to as a second opening OPCF of the color filter because light is transmitted. The second opening OPCF corresponds to the region where only one color filter is present and is located within the light blocking area of the color filter where at least two color filters are overlapped.

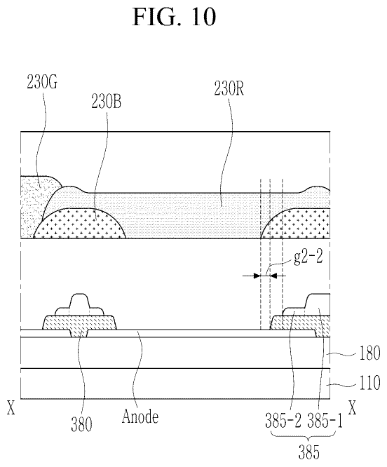

Referring to FIG. 7, the light blocking area of the color filter where at least two color filters are overlapped is positioned only in the area that overlaps the pixel defining layer 380 on a plane, and one side of the light blocking area of the color filter is placed inward from the corresponding side of the pixel defining layer 380. That is, a width of the pixel defining layer 380 may be greater than a width of the light blocking area of the color filter. However, depending on the cross-sectional line, one side of the light blocking area of the color filter may be disposed outside of the corresponding side of the pixel defining layer 380 (see FIG. 10). That is, a width of the light blocking area of the color filter may be greater than a width of the pixel defining layer 380.

The area of the second opening OPCF may be larger than the opening OP of the pixel defining layer 380. In a plan view, a portion of the opening OP of the pixel defining layer 380 may be located outside the second opening OPCF of the color filter and may be overlapped with and obscured by the light blocking area of the color filter.

Furthermore, one side of the spacer 385 is positioned inward by a certain distance g1 from the corresponding side of the pixel defining layer 380, and the spacer 385 is also positioned inward from one side of the light blocking area of the color filter. As a result, when viewed from the front of the display panel DP, the spacer 385 may not be visible because it is obscured by the light blocking area of the color filter.

When external light is incident, it may pass through the second opening OPCF of the color filter and then be reflected on the sidewall of the opening OP of the pixel defining layer 380. The sidewall of the opening OP of the pixel defining layer 380 is curved and color separation occurs depending on the position of reflection, so that the reflected light can appear in various colors, such as a rainbow.

Since this color-separated reflected light can easily be seen by the user and deteriorates the display quality, in an embodiment of the present disclosure, the second opening OPCF of the color filter is formed in a circular shape as depicted in FIG. 8, etc. The opening OP of the pixel defining layer 380 is formed in an oval shape. The direction or eccentricity of the oval shape is arranged in various ways to reduce color separation or allow white reflected light to be visible.

Here, the oval may have two foci and may have a shape on which the sum of the distances to the two foci from each points is constant. The oval may have a major axis and a minor axis. The eccentricity of an ellipse is the value obtained by dividing the distance between two foci by the length of the major axis. When the eccentricity is 0, it is a circle, and when it is 1, it forms a parabola, so an ellipse has an eccentricity value that is greater than 0 and less than 1.

Depending on the embodiment, the opening OP of the pixel defining layer 380 may have a shape similar to an oval rather than an oval, and its direction or eccentricity may be changed in various ways.

Depending on the embodiment, the opening OP of the pixel defining layer 380 may be formed in a polygonal shape that is elongated in one direction. Examples of such polygons may include n-sided polygons such as hexagons and octagons (n may be formed as an integer of 3 or more). The second opening OPCF of the color filter may be formed as a corresponding n-sided polygon or a different n-sided polygon shape.

A planarization layer 550 covering the color filters 230R, 230G, 230B is disposed on the color filters 230R, 230G, 230B. The planarization layer 550 is used to planarize the upper surface of the light emitting display panel, and may be a transparent organic insulating layer containing one or more materials selected from the group consisting of polyimide, polyamide, acrylic resin, benzocyclobutene, and phenol resin.

Depending on the embodiment, a low refractive layer and an additional planarization layer may be further disposed on the planarization layer 550 to improve front visibility and the efficiency of light output from the display panel. Light may be refracted and emitted toward the front by the low refractive layer and the additional planarization layer with high refractive characteristics. Depending on the embodiment, the planarization layer 550 may be omitted and a low refractive layer and an additional planarization layer may be disposed directly on the color filter.

In an embodiment, a cover window (see WU in FIG. 3) including an anti-reflection layer (ARL in FIG. 3) may be disposed on top of the planarization layer 550, and a polarizer may not be disposed on.

The polarizer may prevent the degradation of display quality caused by external light entering and reflected off the anode or the sidewall of the opening OP of the pixel defining layer 380, which is visible to the user. However, the polarizer not only reduces the reflection of external light but also decreases the light emitted from the light emitting layer EML such that it is disadvantageous in consuming more power to display a certain luminance. In order to reduce power consumption, the light emitting display device of the present disclosure may not include a polarizer.

In addition, in an embodiment, the side of the anode is covered with the pixel defining layer 380 to reduce the degree of reflection from the anode, and a light blocking area of the color filter in which at least two or more color filters are overlapped is also formed to block the light. Therefore, there is no need to separately form the polarizer on the front of the light emitting display panel DP.

Hereinafter, various structures of the light emitting display panel DP formed in the display area DA, with reference to FIGS. 8 to 10, where the second opening OPCF of the color filter is formed in a circular shape, and the opening OP of the pixel defining layer 380 is formed in an oval shape will be discussed in detail.

FIG. 8 is a plan view of a portion of a display panel according to an embodiment.

In FIG. 8, only the opening OP of the pixel defining layer 380 and the second opening OPCF of one color filter corresponding thereto are shown. The second opening OPCF of the color filter has a circular shape, and the opening OP of the pixel defining layer 380 has an oval shape. Additionally, the second opening OPCF of the color filter overlaps a portion of the opening OP of the pixel defining layer 380, and the remaining portion of the opening OP of the pixel defining layer 380 is covered with the light blocking area of the color filter. As a result, the light emitting layer located within the opening OP of the pixel defining layer 380 may be partially obscured by the light blocking area of the color filter. In FIG. 8, a part of the opening OP of the pixel defining layer 380 is shown in a dotted line to indirectly show that the corresponding part is positioned below the light blocking area of the color filter.

In an embodiment of FIG. 8, due to errors during actual processing, the portion of the opening OP of the pixel defining layer 380 that is covered by the light blocking area of the color filter may not be constant on both the top and bottom sides, and the area on one side may be larger than the other. Additionally, one side of the opening OP of the pixel defining layer 380 may be located within or in contact with the second opening OPCF of the color filter, and only the other side may be covered by the light blocking area of the color filter.

As shown in FIG. 8, if a portion of the opening OP of the pixel defining layer 380 is covered by the light blocking area of the color filter, the light emitted from the light emitting layer EML within the opening OP may not be provided to the front, thereby reducing light efficiency. However, the size of the opening OP of the pixel defining layer 380 is related to the lifespan of the light emitting layer EML located therein, so the size of the opening OP may not be reduced in order to maintain the lifespan at a certain level.

Referring to FIG. 8, the radius of the major axis of the opening OP of the pixel defining layer 380 is shown as Rop2, the radius of the minor axis is shown as Rop1, and the radius of the second opening OPCF of the color filter is shown as Ropcf. Therefore, the distance from the point where the boundaries of the two openings meet to the center is the same as Ropcf, but at other locations, the boundary of the opening OP of the pixel defining layer 380 is located farther or closer to the center.

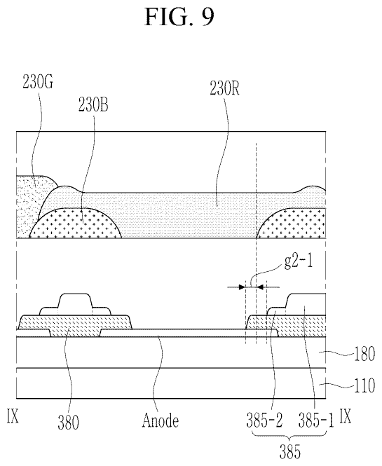

In FIG. 8, the IX-IX line and the X-X line correspond to the minor axis direction and the major axis direction respectively, and also correspond to the cross-sectional lines which serve as the basis for FIGS. 9 and 10.

Depending on the embodiment, the major axis direction of the opening OP of the pixel defining layer 380 may be arranged in various ways. The angle formed by the major axis may have four or more angles, and these angles may be arranged at intervals of 45 degrees or less. The angles of the major axis may be arranged at regular intervals, or may be arranged at irregular intervals.

Since elliptical shapes have different shapes depending on eccentricity even if they have the same area, depending on the embodiment, the opening OP of the pixel defining layer 380 may be formed as an ellipse with different eccentricities.

The opening OP of the pixel defining layer 380 and the second opening OPCF of the color filter corresponding thereto may have spacing that varies within a horizontal spacing range of 0 μm or more and 20 μm or less.

Hereinafter, the cross-sectional structure will be explained through FIGS. 9 and 10.

FIG. 9 and FIG. 10 are schematic cross-sectional views of the embodiment of FIG. 8.

FIG. 9 is a cross-sectional view taken along the cross-sectional line IX-IX of FIG. 8, and FIG. 10 is a cross-sectional view taken along the cross-sectional line X-X of FIG. 8.

FIGS. 9 and 10 are schematic cross-sectional views with some layers removed when compared to FIG. 7, and only the parts necessary to explain the positional relationship are shown.

FIG. 9 is a cross-sectional view taken along the minor axis direction of the opening OP of the pixel defining layer 380, so the opening OP of the pixel defining layer 380 is located inside the boundary of the second opening OPCF of the color filter. The width of the opening OP of the pixel defining layer 380 is narrower than the width of the second opening OPCF of the color filter, and the gap between the boundaries of the two openings OP, OPCF is g2-1. Here, the gap g2-1 may be equal to the value obtained by subtracting Rop1, which is the minor axis radius of the opening OP of the pixel defining layer 380, from Ropcf, which is the radius of the second opening OPCF of the color filter.

A cross-sectional view taken along a cross-section line adjacent to the minor axis direction may also have the same structure as FIG. 9. The interval g2-1 may have a minimum value when it is a cross-sectional view taken along the minor axis, and may have a value greater than the minimum value when it is cut along a sectional line around the minor axis.

FIG. 10 is a cross-sectional view taken along the major axis direction of the opening OP of the pixel defining layer 380, so the opening OP of the pixel defining layer 380 is located outside the boundary of the second opening OPCF of the color filter. The width of the opening OP of the pixel defining layer 380 is wider than the width of the second opening OPCF of the color filter, and the gap between the boundaries of the two openings OP, OPCF is g2-2. Here, the gap g2-2 may be equal to the value obtained by subtracting Ropcf, which is the radius of the second opening OPCF of the color filter, from Rop2, which is the major axis radius of the opening OP of the pixel defining layer 380.

A cross-sectional view taken along a cross-sectional line adjacent to the major axis direction may also have the same structure as that shown in FIG. 10. The interval g2-2 may have the maximum value when it is a cross-sectional view taken along the major axis, and may have a value smaller than the maximum value when it is taken along the sectional line around the major axis.

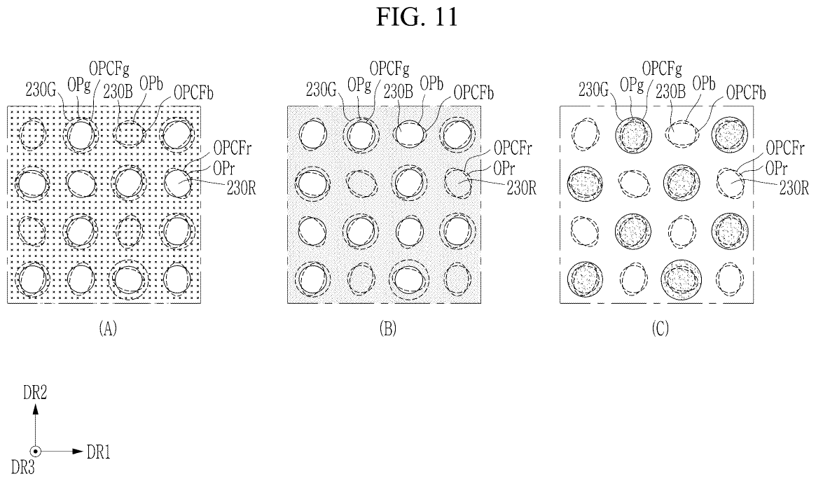

In the above, we have looked at the structure formed after three color filters 230R, 230G, 230B are sequentially stacked. Hereinafter, the planar structure of each of the color filters 230R, 230G, 230B will be explained in detain with reference to FIG. 11.

FIG. 11 is a plan view illustrating color filters of a display area according to an embodiment.

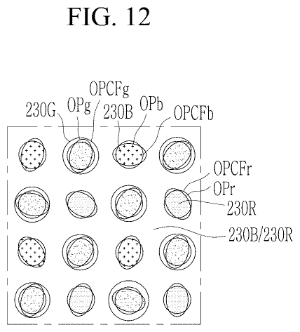

FIG. 11 (A) shows the layer where the blue color filter 230B is formed, and hatching is drawn at the portion where the blue color filter 230B is located. The remaining layers in FIG. 12 are shown with dotted lines.

Referring to FIG. 11 (A), the blue color filter 230B is located in the light blocking area and the blue light transmission area through which blue light is transmitted. The blud color filter 230B is not formed in the red and green transmission areas.

FIG. 11 (B) shows the layer where the red color filter 230R is formed, and hatching is drawn at the portion where the red color filter 230R is located. The remaining layers in FIG. 12 are shown with dotted lines.

Referring to FIG. 11 (B), the red color filter 230R is located in the light blocking area and the red light transmission area through which red light is transmitted. The red color filter 230R is not formed in the blue and green transmission areas.

FIG. 11 (C) shows the layer where the green color filter 230G is formed, and hatching is drawn at the portion where the green color filter 230G is located. The remaining layers in FIG. 12 are shown with dotted lines.

Referring to FIG. 11 (C), the green color filter 230G is formed in an island-like structure and is located only in the green light transmission area through which green light is transmitted. The green color filter 230G is not formed in the light blocking area and the red and blue transmission areas. The green color filter 230G may overlap with some of the light blocking areas of the color filter.

By overlapping FIG. 11 (A), (B), and (C), a planar structure as illustrated in FIG. 12 may be obtained.

FIG. 12 is a plan view of a portion of a display panel according to an embodiment.

FIG. 12 is a plan view corresponding to an embodiment, in which the second opening of the color filter and the opening of the pixel defining layer each have different directions or different sizes. The eccentricity of the elliptical shapes of the opening of the pixel defining layer may also vary depending on the color. In FIG. 12, the second opening of the color filter is divided into a red second opening OPCFr, a green second opening OPCFg, and a blue second opening OPCFb, and the opening of the pixel defining layer is also divided into a red opening OPr, a green opening OPg, and a blue opening OPb.

The blue color filter 230B and the red color filter 230R are sequentially overlapped to form a light blocking area, and the green color filter 230G has an island-shaped structure. Here, the boundary of the green color filter 230G is further shown outside the green second opening OPCFg among the second openings of the color filter, so that it is clearly shown that the green color filter 230G has an island-shaped structure and the boundary of the green color filter 230G partially overlaps with the light blocking area of the color filter. In FIG. 12, the red color filter 230R and the blue color filter 230B are each located in a light blocking area, but hatching corresponding to the red color filter 230R and the blue color filter 230B are not shown in the light blocking area. Instead, “230B/230R” clearly indicates that the light blocking area is where the blue color filter 230B and the red color filter 230R are overlapped with each other.

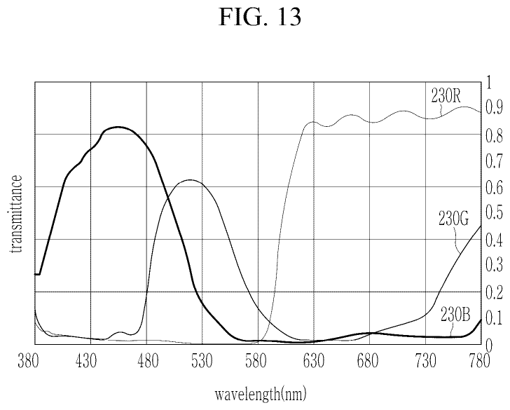

In the following, we will see, with reference to FIG. 13, whether two stacked color filters may replace a light blocking layer.

FIG. 13 is a graph showing the transmittance according to the wavelength of the color filter.

FIG. 13 is a graph of transmittance for the wavelengths of each color filter 230R, 230G, 230B, so light in the wavelength range indicated at a high point is transmitted.

Referring to FIG. 13, each color filter 230R, 230G, 230B has a transmittance rate of less than 10% for parts other than the wavelength band that passes through it. When three or two color filters are overlapped, there is virtually no wavelength band that passes through. Therefore, overlapping at least two color filters may substitute for a light blocking member. By overlapping three color filters (see FIG. 19) or by overlapping two color filters as described above (see FIG. 7, etc.), it is confirmed that the light blocking layer may be replaced.

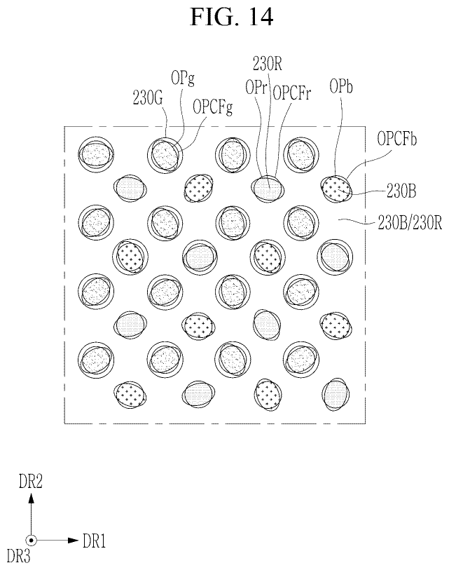

Referring to FIG. 12, the second opening of the color filter corresponding to each color and the opening of the pixel defining layer may have different directions or sizes. One of these embodiments is examined with reference to FIG. 14.

FIG. 14 is a plan view of a portion of a display panel according to an embodiment.

In FIG. 14, the opening OP of the pixel defining layer 380 and the second openings OPCF of the color filter, corresponding to each light emitting layer EML that displays the primary colors of red, green and blue, are respectively shown as openings OPr, OPg, OPb and second openings OPCFr, OPCFg, OPCFb. Here, r, g, b may correspond to red, green, and blue, respectively.

FIG. 14 is an embodiment in which the openings OPr, OPg, OPb of the pixel defining layer 380 having an elliptical shape are formed at various angles and with various eccentricities. Specifically, the openings for each color OPr, OPg, OPb have different eccentricities. The openings of the same color OPr, OPg, OPb have the same eccentricity, but are arranged in different directions of the major axis. Openings OPr, OPg, OPb corresponding to different colors may also be arranged in different directions of the major axis. However, some openings OPr, OPg, OPb may be arranged in the same direction of the major axis even if they correspond to different colors. The second openings OPCFr, OPCFg, OPCFb of the color filter may have different radius from each color.

Through FIG. 14, the planar structures of the openings OPr, OPg, OPb of the pixel defining layer 380 and the second openings OPCFr, OPCFg, OPCFb of the color filter are examined in detail as follows.

In FIG. 14, each of the red opening OPr, the green opening OPg, and the blue opening OPb of the pixel defining layer 380 may be an ellipse with a different eccentricity. In addition, the red second opening OPCFr, the green second opening OPCFg, and the blue second opening OPCFb of the color filter may have circular shapes with different radii and different areas. Here, the eccentricities of the openings OPr, OPg, OPb of the pixel defining layer 380 may have a value ranging from 0.2 to 0.85.

Each of the openings OPr, OPg, OPb of the pixel defining layer 380 may correspond to each of the second openings OPCFr, OPCFg, OPCFb. The second openings OPCFr, OPCFg, OPCFb of the corresponding color filters and the openings OPr, OPg, OPb of the pixel defining layer 380 may overlap with each other at least partially on a plane. Since the second openings OPCFr, OPCFg, OPCFb of the corresponding two color filters and the openings OPr, OPg, OPb of the pixel defining layer 380 have different planar shapes, the horizontal gap between the boundaries of the two openings may vary. Here, the horizontal interval between the second openings OPCFr, OPCFg, OPCFb of the color filter and the corresponding openings OPr, OPg, OPb of the pixel defining layer 380 may vary within the range of 0 μm to 20 μm. Depending on the embodiment, it may vary from 4.5 μm to 10 μm.

In an embodiment of FIG. 7, the angle formed by each major axis of the plurality of openings OPr, OPg, OPb of the pixel defining layer 380 may form four or more different angles. Additionally, the angle formed by the major axis may be arranged at intervals of 45 degrees or less.

As an example, in an embodiment having five different angles, the angles of the major axes are arranged at intervals of 36 degrees. So if one major axis is aligned at 0 degrees relative to the first direction DR1, the other angles would be 36 degrees, 72 degrees, 108 degrees, and 144 degrees.

In other words, the interval between the angles of the major axis may be obtained by dividing the angle of 180 degrees by 5, which is the number of directions. This method works because the two angles that form 180 degrees from each other represent the same direction of the major axis of the ellipse. Thus, dividing 180 degrees by the number of angles provides the necessary spacing for the major axis direction of the oval-shaped opening OP of the pixel defining layer 380.

As described above, the major axes of the plurality of openings OPr, OPg, OPb of the pixel defining layer 380 may be arranged at the same intervals at a specific angle of 45 degrees or less. However, depending on the embodiment, the angle formed by the major axis of each opening may be one of 45 degrees or less and may be arranged at irregular intervals. The embodiment in which the major axes of the openings are arranged at irregular intervals may be intentionally arranged to reduce the diffraction pattern, or may be arranged at irregular intervals due to processing errors.

In order to make a unit pixel, that includes openings of red, green, and blue, have a square structure, it may be appropriate to form it by distinguishing the number corresponding to the square of an integer for the angle of the major axis, for example, 22, 32, 42, 52, etc. Here, the unit pixel may include one each of red, green, and blue openings, and a plurality of openings of one color, for example, green openings, may be formed.

Since the horizontal gap between the boundaries of the openings OPr, OPg, OPb of the pixel defining layer 380 and the second openings OPCFr, OPCFg, OPCFb of one color filter is not constant and changes depending on the position, the intensity at which external light is reflected may vary. Here, since the plurality of openings OPr, OPg, OPb of the pixel defining layer 380 having an elliptical shape are arranged in various directions at four or more angles, the reflection intensity of external light depending on the angle may be strong or weak. As they mix together, they are alleviated overall, which can have the advantage of causing less color separation of external light or creating a constant diffraction pattern or color separation regardless of the angle.

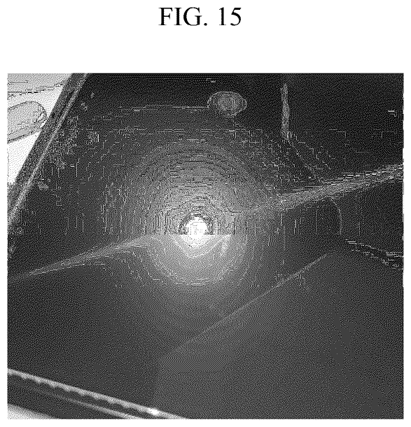

FIG. 15 is a photograph capturing the reflection characteristics of external light for the embodiment of FIG. 14.

In FIG. 15, a photograph is taken after positioning a light source close to the light emitting display device formed according to an embodiment of FIG. 14 and illuminating it to capture the reflected light. According to this method, the degree of reflection of external light may be enhanced and easily confirmed.

Referring to FIG. 15, although a diffraction pattern of external light occurs, the clarity is reduced, resulting in a mitigated state as captured in the photograph.

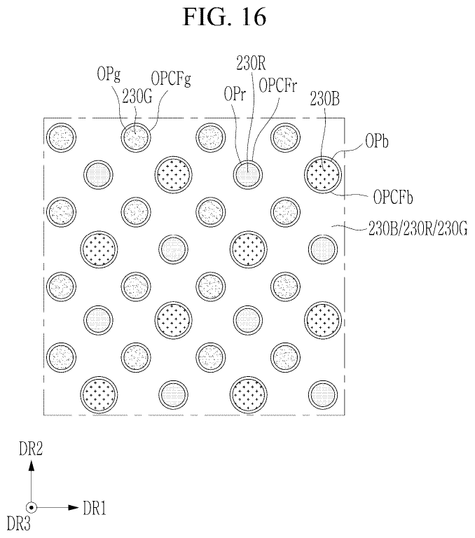

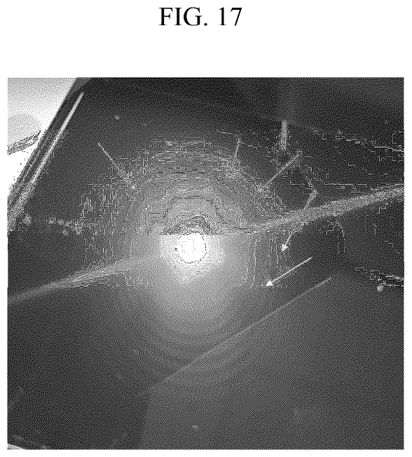

In order to compare the reflection characteristics of the external light of FIG. 15 with the comparative example, the planar structure of the comparative example and the reflection characteristics of the external light in the comparative example will be discussed below with reference to FIGS. 16 and 17.

FIG. 16 is a plan view of a portion of the display panel according to the comparative example, and FIG. 17 is a photograph capturing the reflection characteristics of external light for the comparative example of FIG. 16.

In the comparative example of FIG. 16, unlike the embodiment of FIG. 14, the second openings OPCFr, OPCFg, OPCFb of the color filter and the openings OPr, OPg, OPb of the pixel defining layer 380 are all formed in a circular shape.

Referring to FIG. 17, in the comparative example, the diffraction pattern is formed in a ring shape, and color separation like a rainbow is visible in the area indicated by the arrow. In contrast, in the embodiment of FIG. 15, color separation is not visible in the corresponding portion and the intensity of the diffraction pattern is relatively weak.

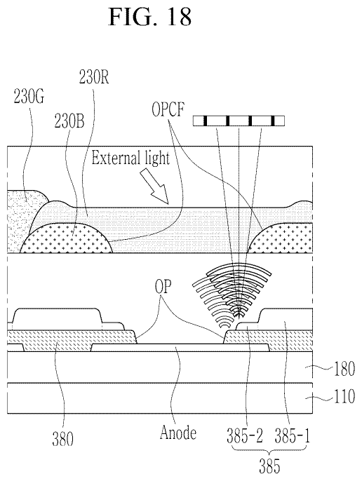

The principle of occurrence of the difference in intensity of the diffraction pattern as described above will be examined with reference to FIG. 18.

FIG. 18 is a diagram explaining the principle of diffraction pattern occurring due to the reflection of external light.

When external light is incident, it may pass through the second opening OPCF of the color filter and then be reflected from the sidewall and top surface of the pixel defining layer 380, and some of the external light may be reflected from the sidewall and top surface of the spacer 385. Since the sidewall and top surface of the pixel defining layer 380 have different angles, external light is reflected over a wide area. The spacer 385 is divided into a first part 385-1 that is tall and located in a narrow area, and a second part 385-2 that is low in height and is located in a wide area. When external light is reflected from the side and top surface of the first part 385-1 and the side and/or top surface of the second part 385-2, it is reflected over a wide area.

External light reflected in this way may form a diffraction pattern through constructive interference and destructive interference, and the user may perceive this diffraction pattern.

However, in the present disclosure, as the pixel defining layer 380 may be partially covered by a light blocking area of a color filter, external light is not reflected from the pixel defining layer 380 and the diffraction pattern may be alleviated. In addition, since the second opening OPCF of the color filter is formed in a circular shape and the opening OP of the pixel defining layer 380 has an oval shape, the horizontal gap between the two openings varies depending on the position/angle. As it changes variously, irregular reflection of external light may occur, and the overall reflection characteristics may be alleviated. In addition, since the major axis direction of the opening OP of the pixel defining layer 380 is formed in various orientations, the positions where the pixel defining layer 380 is exposed and external light can be reflected are also varied. This causes the external light to mix, resulting in an overall mitigated diffraction pattern. As the diffraction pattern is alleviated in this way, the degree of color separation is also alleviated. Since the degree of diffraction pattern and color separation due to reflection of external light is reduced, it becomes difficult for the user to recognize the deterioration in display quality, and as a result, the display quality of the display device may be improved.

In the above, we looked at an embodiment in which the light blocking area of the color filter is formed by overlapping two color filters. However, depending on the embodiment, the light blocking area of the color filter may be formed by overlapping three color filters, which will be discussed with reference to FIG. 19.

FIG. 19 is a schematic cross-sectional view of a display panel according to an embodiment.

FIG. 19 is a diagram corresponding to FIG. 7, and is different from FIG. 7 in that the green color filter 230G overlaps with all of the light blocking areas of the color filter, and other parts are the same as FIG. 7.

In FIG. 7, a light blocking layer that is formed in black and blocks visible light may not be formed. Instead of the light blocking layer, three color filters are overlapped to block visible light. In the light blocking area of the color filter, the blue color filter 230B, a red color filter 230R, and the green color filter 230G are sequentially stacked. The order in which color filters are stacked may vary depending on the embodiment.

Specifically, color filters 230R, 230G,230B are disposed on the third sensing insulating layer 511. Each of the color filters 230R, 230G, 230B may be positioned to overlap the anode of the light emitting diode on a plane. Since the light emitted from the light emitting layer EML may change to a corresponding color as it passes through a color filter, all light emitted from the light emitting layer EML may have the same color. The light emitting layer EML may emit light of different colors, and the displayed color can be enhanced after passing through a color filter of the same color.

Depending on the embodiment, the color filters 230R, 230G, 230B may be replaced with a color conversion layer or may further include a color conversion layer. The color conversion layer may include quantum dots.

In the embodiment of FIG. 19, the light blocking layer that is formed in black and blocks visible light is not formed, and instead of the light blocking layer, a light blocking area of a color filter where three color filters are overlapped with each is formed to replace the light blocking layer. In the embodiment of FIG. 19, the light blocking area of the color filter includes the blue color filter 230B, a red color filter 230R, and the green color filter 230G sequentially stacked.

In the color filter, each areas other than the light blocking area of the color filter may include only a single color filter. The area where only the single color filter is disposed may form a light transmitting area of the color filter, and may also be referred to as a second opening OPCF of the color filter.

The spacer 385 may be positioned inward by a certain distance g1 from one side of the pixel defining layer 380, and the spacer 385 may also be positioned inward from one side of the light blocking area of the color filter. As a result, when viewed from the front of the display panel DP, the spacer 385 may not be visible because it is covered by the light blocking area of the color filter.

When external light is incident, it may pass through the second opening OPCF of the color filter and then be reflected on the sidewall of the opening OP of the pixel defining layer 380. The sidewall of the opening OP of the pixel defining layer 380 is curved and color separation may occur depending on the position of reflection, which causes the reflected light to appear in various colors, such as a rainbow. Since this color-separated reflected light may easily be perceived by the user and degrade the display quality, in an embodiment of the present disclosure, the second opening OPCF of the color filter is formed in a circular shape as illustrated in FIG. 8, etc., and the opening OP of the pixel defining layer 380 is formed in an oval shape. The oval direction or eccentricity of the oval may be changed in various ways to reduce the color separation or to allow white reflected light to be visible. Depending on the embodiment, the opening OP of the pixel defining layer 380 may be formed to have a shape similar to an oval rather than an oval, and its direction or eccentricity may be changed in various ways.

According to an embodiment, the opening OP of the pixel defining layer 380 may be formed in a polygonal shape that is elongated in one direction. As an example of the polygon, the opening OP of the pixel defining layer 380 may be formed as a n-sided polygon (where n is an integer of 3 or more) such as a hexagon or octagon, and the second opening OPCF of the color filter may be formed as a corresponding n-sided polygon or a different shape of n-sided polygon.

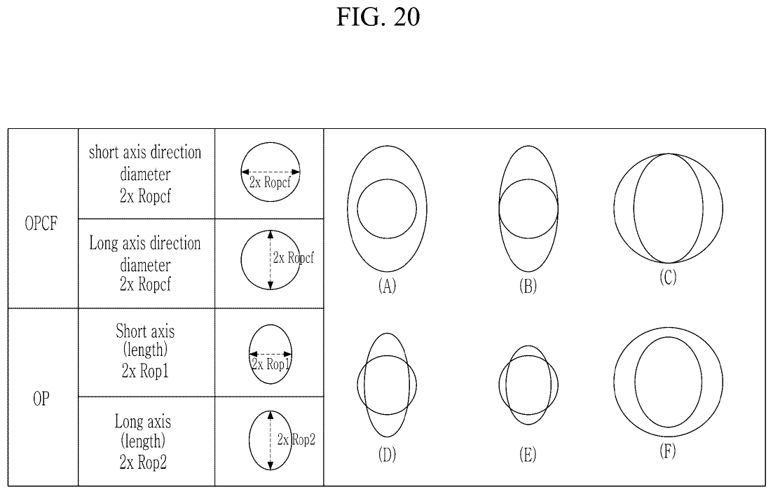

Hereinafter, various embodiments having the elliptical opening OP of the pixel defining layer 380 and the circular second opening OPCF of the color filter are explained with reference to FIG. 20.

FIG. 20 is a table showing various embodiments.

In FIG. 20, the diameter of the second opening OPCF of the color filter and the length of the opening OP of the pixel defining layer 380 are classified according to the major axis direction and the minor axis direction of the opening OP of the pixel defining layer 380.

First, since the second opening OPCF of the color filter has a circular shape, it has a constant diameter value (2× Ropcf) regardless of the major and minor axis directions of the opening OP of the pixel defining layer 380. Since the opening OP of the pixel defining layer 380 has an elliptical shape, the lengths in the major axis direction and the minor axis direction are different. The length in the minor axis direction of the opening OP may be 2× Rop1, while the length in the major axis direction of the opening OP may be 2× Rop2.

Six embodiments are shown based on the size relationship between diameter of the second opening OPCF and major/minor axis length of the opening OP.

FIG. 20 (A) shows an embodiment in which the length of the opening OP of the pixel defining layer 380 in the minor axis direction is longer than the diameter of the second opening OPCF of the color filter. The length of the major axis of the opening OP of the pixel defining layer 380 is longer than the diameter. The second opening OPCF of the color filter is positioned within the opening OP of the pixel defining layer 380 in a plan view.

FIG. 20 (B) shows an embodiment in which the diameter of the second opening OPCF of the color filter and the length of the minor axis direction of the opening OP of the pixel defining layer 380 are the same. However, the length of the opening OP of the pixel defining layer 380 in the major axis direction is longer than the diameter. The second opening OPCF of the color filter and the opening OP of the pixel defining layer 380 may contact each other at two points on the plane.

FIG. 20 (C) shows an embodiment in which the diameter of the second opening OPCF of the color filter and the length of the major axis direction of the opening OP of the pixel defining layer 380 are the same, and the length of the opening OP of the pixel defining layer 380 in the minor axis direction is shorter than the diameter of the second opening OPCF. The second opening OPCF of the color filter and the opening OP of the pixel defining layer 380 may contact each other at two points on the plane.

FIG. 20 (D) and FIG. (E) show an embodiment in which the length in the minor axis direction of the opening OP of the pixel defining layer 380 is shorter than the diameter of the second opening OPCF of the color filter, and the length of the opening OP of the pixel defining layer 380 in the major axis direction is longer than the diameter of the second opening OPCF. The second opening OPCF of the color filter and the opening OP of the pixel defining layer 380 may intersect each other at 4 points on the plane.

FIG. 20 (F) shows an embodiment in which the diameter of the second opening OPCF of the color filter is longer than the length of the minor axis direction and the length of the major axis direction of the opening OP of the pixel defining layer 380. The opening OP of the pixel defining layer 380 is positioned within the second opening OPCF of the color filter in a plan view.

The various embodiments described in FIG. 20 are just examples of the embodiments, so embodiments not described here are also possible. For example, the diameter of the second opening OPCF of the color filter may be shorter than the length of the minor axis direction of the opening OP of the pixel defining layer 380.

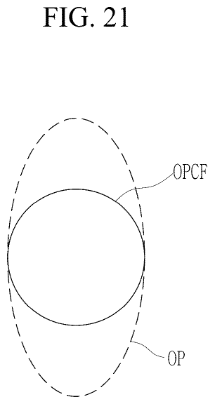

Some of the embodiments shown in FIG. 20 will be discussed in more detail with reference to FIGS. 21 to 26.

First, let's look at the embodiment of FIG. 20 (B) in detail through FIGS. 21 to 23.

FIG. 21 to FIG. 23 are plan views of a portion of a display panel according to an embodiment.

In FIG. 21, only one opening OP of a pixel defining layer and the corresponding second opening OPCF of one color are shown. This figure has a similar shape to FIG. 20 (B), but, in FIG. 21, the opening OP of the pixel defining layer is depicted in a dotted line.

Here, the dotted line represents the portion of the border of the opening OP of the pixel defining layer that overlaps with the light blocking area of the color filter and is hidden when viewed from the front. That is, in FIG. 21, the pixel defining layer is located outside the opening OP, and the light blocking area of the color filter is also located outside the second opening OPCF.

In the embodiment of FIG. 21, the opening OP of the pixel defining layer 380 has an oval shape, and the second opening OPCF of the color filter has a circular shape. The second opening OPCF of the color filter in a circular shape may contact the opening OP of the pixel defining layer 380 in an oval shape at two points.

In an embodiment of FIG. 21, the length of the minor axis of the oval-shaped opening OP of the pixel defining layer 380 is equal to the diameter of the circular-shaped second opening OPCF of the color filter, and the length of the oval-shaped opening OP of the pixel defining layer 380 is longer than the diameter of the circular-shaped second opening OPCF of the color filter. Here, the half of the major axis length of the oval-shaped opening OP may be greater than the radius of the circular-shaped second opening OPCF by 0 μm to 20 μm, and depending on the embodiment, it may be greater in a range from 4.5 μm to 10 μm. The length of the major axis of the oval-shaped opening OP may change the horizontal spacing depending on the thickness of the layer (e.g., encapsulation layer) located between the light blocking area of the color filter and the pixel defining layer 380 in a thickness direction, and the encapsulation layer may have a thickness of approximately 6 μm.

In an embodiment of FIG. 21, the opening OP of the pixel defining layer 380 and the second opening OPCF of the color filter contact at two points on the plane, but due to actual processing errors, a portion of one side of the opening OP may be covered by the light blocking area of the color filter without overlapping with the second opening OPCF of the color filter.

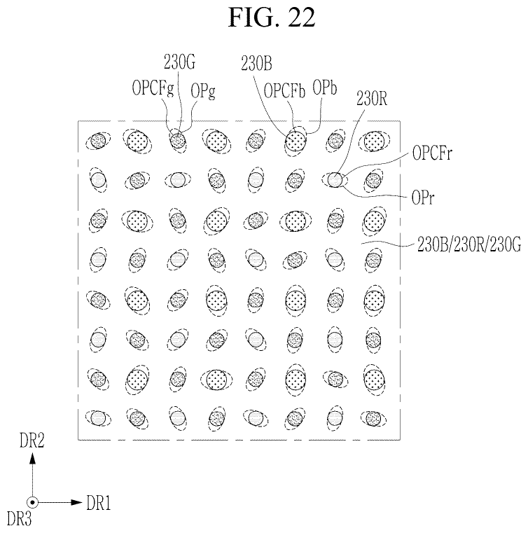

The eccentricity of the oval-shaped opening OP of the pixel defining layer 380 may vary depending on the embodiment, and the orientation of the major axis of the opening OP of the pixel defining layer 380 may also vary. Therefore, the opening OP of the pixel defining layer 380 and the second opening OPCF of the color filter having the same structure as in FIG. 21 may be arranged as shown in FIG. 22 in the display area.

In FIG. 22, based on the light emitting layers displaying the three primary colors of red, green, and blue, the opening OP of the pixel defining layer 380 corresponding to each light emitting layer and the second openings OPCF of the color filter are shown separately. These are designated as OPr, OPg, OPb for the opening OP of the pixel defining layer 380 and OPCFr, OPCFg, OPCFb for the second opening OPCF of the color filter. Here, r, g, and b may correspond to red, green, and blue, respectively.

Each of the openings OPr, OPg, OPb of the pixel defining layer 380 may be arranged at various angles, and the red opening OPr, green opening OPg, and blue opening OPb of the pixel defining layer 380 may have different eccentricities. Each of the openings OPr, OPg, OPb of the same color may be formed with the same or different eccentricity. Here, the eccentricity of the opening OP of the pixel defining layer 380 may range from 0.2 to 0.85.

The red second opening OPCFr, the green second opening OPCFg, and the blue second opening OPCFb of the color filter may be formed as circles with different radii. The second opening OPCFr, OPCFg, OPCFb of the same color may have the same or different radii.

The openings OPr, OPg, OPb of the pixel defining layer 380 correspond to the second openings OPCFr, OPCFg, OPCFb having the same color. In each opening OPr, OPg, OPb of the pixel defining layer 380, the second openings OPCFr, OPCFg, OPCFb of the color filter corresponding to each opening OPr, OPg, OPb of the pixel defining layer 380 is positioned in a plan view. The second openings OPCFr, OPCFg, OPCFb of the corresponding color filters and the openings OPr, OPg, OPb of the pixel defining layer 380 may overlap with each other on a plane.

In FIG. 22, the openings OPr, OPg, OPb of the pixel defining layer 380 are arranged in various orientation, and the angles at which the openings OPr, OPg, OPb of the pixel defining layer 380 may be explained based on the major axis direction of the oval-shaped opening OPr, OPg, OPb of the pixel defining layer 380. According to an embodiment, the major axes of the openings OPr, OPg, OPb of the pixel defining layer 380 may form four or more different angles. Additionally, the angles formed by the major axis may be arranged at intervals of 45 degrees or less.

As an example, focusing on an embodiment with five angles, the relationship is as follows. In an embodiment with five different angles, the major axes are arranged at intervals of 36 degrees. If one major axis is aligned at 0 degrees relative to the first direction DR1, the other angles would be 36 degrees, 72 degrees, 108 degrees, and 144 degrees, resulting in a total of five different angles. In other words, by dividing the angle of 180 degrees by 5, which is the number of directions, we can verify the interval between the angles of the major axis. That is, as angles that add up to 180 degrees represent the same major axis direction of the oval shape, dividing 180 degrees by 5 would result in an interval of 36 degrees for the angels of each major axis.

The openings OPr, OPg, OPb of the pixel defining layer 380 may be arranged at equal intervals at a specific angle of 45 degrees or less. However, depending on an embodiment, the angle formed by each of the major axis of the openings OPr, OPg, OPb of the pixel defining layer 380 may be 45 degrees or less, and may be arranged at irregular intervals.

The embodiment in which the major axes of the openings are arranged at irregular intervals may be intentionally arranged to reduce the diffraction pattern, or due to the processing errors.

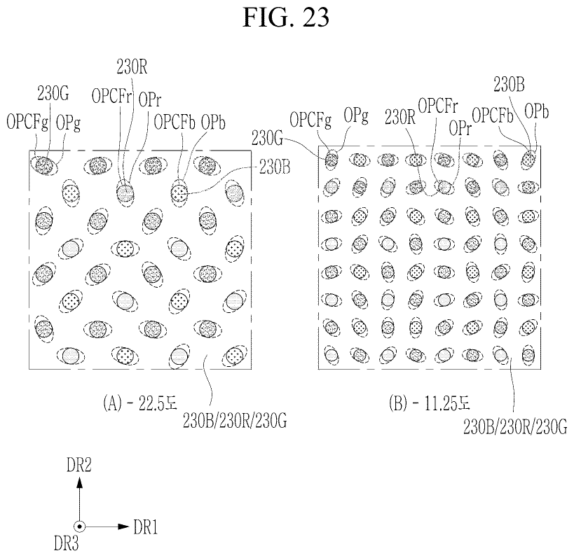

Hereinafter, through FIG. 23, two embodiments having a specific angular interval formed by the major axes of the oval-shaped openings OPr, OPg, OPb of the pixel defining layer 380 in an embodiment of FIG. 21 will be discussed in detain with reference to FIG. 23.

FIG. 23 (A) shows an embodiment in which the major axes of the oval-shaped openings OPr, OPg, OPb of the pixel defining layer 380 are arranged at an angular interval of 22.5 degrees. FIG. 23 (B) is an example in which the major axis of openings OPr, OPg, OPb of the pixel defining layer 380 are arranged at an angle interval of half, that is, 11.25 degrees, compared to FIG. 23 (A).

In an embodiment of FIG. 23 (A) with an angular spacing of 22.5 degrees, the number of angles formed by the major axes of the openings OPr, OPg, OPb of the pixel defining layer 380 having an elliptical shape may be eight. That is, since 180 degrees divided by 8 is 22.5 degrees, the major axes of the openings OPr, OPg, OPb of the pixel defining layer 380 may be arranged in eight directions. Here, the reason for using 180 degrees as the basis for the calculation, rather than 360 degrees, is that two angles differing by 180 degrees represent the same major axis direction.

An embodiment of FIG. 23 (B) with an angular interval of 11.25 degrees has twice as many angles as the embodiment of FIG. 23 (A), and the major axis of openings OPr, OPg, OPb of the pixel defining layer 380 may be arranged in a total of 16 directions.

In the two embodiments as shown in FIG. 23, the major axis arrangement angle of the openings OPr, OPg, OPb of the pixel defining layer 380 may be more than 4. This causes the diffraction patterns to mix without having a specific directionality. As a result, the users are less likely to perceive the diffraction patterns or color separation, and the display quality can be enhanced.

In FIG. 23, the major axis directions of the openings OPr, OPg, OPb of the pixel defining layer 380 are arranged at equal intervals, but depending on the embodiment, they may be arranged at irregular intervals at an angle of 45 degrees or less.

In the above, an embodiment, as illustrated in FIG. 21, where the second opening OPCF of the color filter is formed in a circular shape, the opening OP of the pixel defining layer 380 is formed in an oval shape, and the circular-shaped second opening OPCF and the oval-shaped opening OP are contacted to each other is discussed.

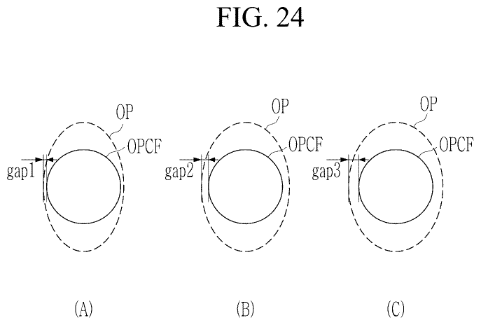

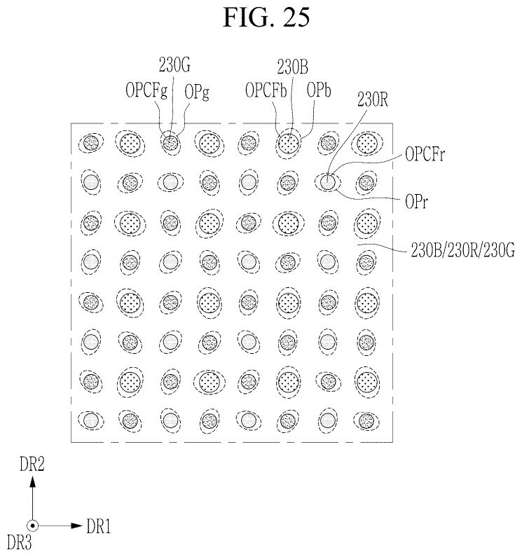

However, either the opening OP of the pixel defining layer 380 or the second opening OPCF of the color filter may be relatively large, and we will discuss the embodiment representing this type of example with reference to FIGS. 24 and 25.

FIG. 24 and FIG. 25 are plan views of a portion of a display panel according to an embodiment.

First, FIG. 24 shows that the second opening OPCF of the color filter can be formed at various intervals gap1, gap2, gap3 depending on how smaller the opening OP of the pixel defining layer 380.

In FIG. 24, the opening OP of the pixel defining layer 380 is larger than the second opening OPCF of the color filter, so that the circular-shaped second opening OPCF of the color filter is positioned within the opening OP of the pixel defining layer 380 in a plan view. Therefore, in the embodiment of FIG. 24, the diameter of the circular-shaped second opening OPCF of the color filter is smaller than the minor axis length of the oval-shaped opening OP of the pixel defining layer 380. The diameter of the circular-shaped second opening OPCF is also smaller than the major axis length of the oval-shaped opening OP. The half of the major axis length of the oval-shaped opening OP may be greater than the radius of the circular-shaped second opening OPCF of the color filter which may range from 0 μm to 20 μm.

Specifically, in FIG. 24 (A), the minimum horizontal gap in the plan view between the second opening OPCF of the color filter and the opening OP of the pixel defining layer 380 is not as large as gap1. But, in FIG. 24 (B), the minimum horizontal gap is gap2 which is relatively larger than gap1, and, in FIG. 24 (C), the minimum horizontal gap is gap3, which is the largest. In FIGS. 24 (A) to 24 (C), the elliptical eccentricity of the opening OP of the pixel defining layer 380 may also be different. Here, the eccentricity of the oval-shaped opening OP may range from 0.2 to 0.85.

In FIG. 24, the opening OP of the pixel defining layer is depicted in a dotted line. The dotted line represents the portion of the border of the opening OP of the pixel defining layer that overlaps with the light blocking area of the color filter and is hidden when viewed from the front.

In the embodiment of FIG. 24, only a portion of the light emitting layer exposed by the opening OP of the pixel defining layer is overlapped with the second opening OPCF of the color filter and is exposed to the front surface. The portion that overlaps with the light blocking area of the color filter may not be perceived from the front surface.

In the embodiment of FIG. 24, due to actual processing errors, one side of the opening OP of the pixel defining layer 380 may overlap the second opening OPCF of the color filter, and may be exposed to the front.

The embodiment having the same structure as FIG. 24 may be arranged in the display area as illustrated in FIG. 25.

FIG. 25 shows an embodiment in which the major axes of the openings OPr, OPg, OPb of the pixel defining layer 380 are arranged at various angles. Additionally, the openings OPr, OPg, OPb of the pixel defining layer 380 in FIG. 25 have different eccentricities for each color. Depending on an embodiment, two openings OPr, OPg, OPb of the pixel defining layer 380 corresponding to the same color may have different eccentricities. Depending on an embodiment, all of the pixel defining layers 380 may have different eccentricities. Additionally, the major axes of the oval-shaped openings OPr, OPg, OPb of the pixel defining layer 380 may be arranged at four or more angles, or may be arranged at intervals of 45 degrees or less.

The embodiment of FIG. 25 may also be arranged with 8 major axis directions at angular intervals of 22.5 degrees, as shown in FIG. 23 (A), or may be arranged with 16 major axis directions at angular intervals of 11.25 degrees, as shown in FIG. 23 (B). In FIG. 23, the major axis directions of the openings OPr, OPg, OPb of the pixel defining layer 380 are arranged at the same intervals, but in some embodiments, they may be arranged at irregular intervals at an angle of 45 degrees or less.

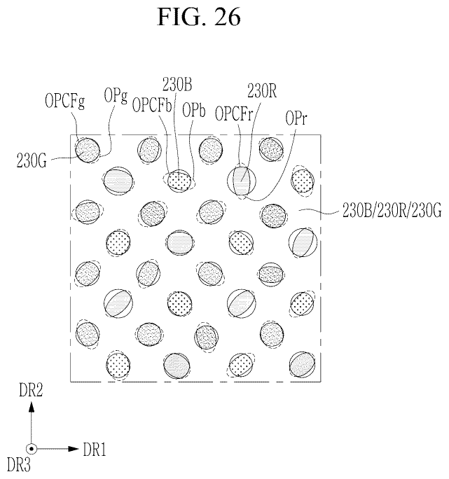

Depending on an embodiment, the diameter of the second opening OPCF of the color filter may be shorter than the major axis length of opening OP of the pixel defining layer 380 and longer than the minor axis length of the opening OP of the pixel defining layer 380. This example will be discussed in detail with reference to FIG. 26.

FIG. 26 is a plan view of a portion of a display panel according to an embodiment.

FIG. 26 is a diagram showing the embodiment of FIG. 20 (D) or FIG. 20 (E) arranged in a display area, where the major axes of the oval-shaped openings OPr, OPg, OPb of the pixel defining layer 380 are arranged in various angles, and the openings OPr, OPg, OPb of the pixel defining layer 380 have different eccentricities for each color. According to an embodiment, two of openings OPr, OPg, OPb corresponding to the same color in the pixel defining layer 380 may have different eccentricities, or all of the openings OPr, OPg, OPb of the pixel defining layer 380 may have the same eccentricity. Additionally, the major axes of the oval-shaped openings OPr, OPg, OPb of the pixel defining layer 380 may be arranged at four or more different angles or may be arranged at intervals of 45 degrees or less.

The embodiment of FIG. 26 may also be arranged with 8 major axis directions at angular intervals of 22.5 degrees, as shown in FIG. 23 (A), or may be arranged with 16 major axis directions at angular intervals of 11.25 degrees, as shown in FIG. 23 (B). In FIG. 26, the major axes directions of the openings OPr, OPg, OPb of the pixel defining layer 380 are arranged at equal intervals, but in some embodiments, they may be arranged at irregular intervals at an angle of 45 degrees or less.

In FIGS. 20(C) and (F), when placed in the display area, the oval shapes may be arranged at various angles and may be arranged at the same or irregular intervals. Additionally, the eccentricity of the oval-shaped opening OP may also be formed with various eccentricities.

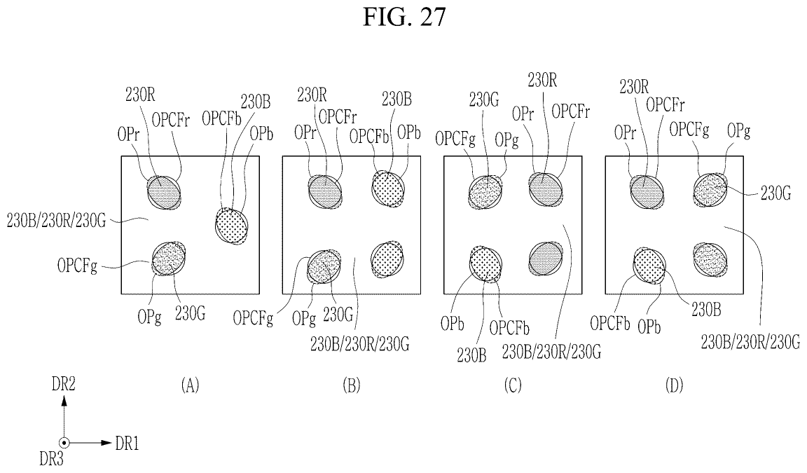

A structure of a unit pixel will be explained in detail with reference to FIG. 27.

FIG. 27 is a plan view showing the configuration of a unit pixel of one of the display panels according to an embodiment.

FIG. 27 (A) shows an example in which a unit pixel includes one red, one green, and one blue light emitting region. Specifically, each of the unit pixel may include a red opening OPr, a green opening OPg and a blue opening OPb of the pixel defining layer 380, and a red second opening OPCFr, a green second opening OPCFg and a blue second opening OPCFb of the color filter.

However, depending on an embodiment, a unit pixel may include fourth light emitting areas with two of these areas emitting the same color.

FIG. 27 (B) shows a unit pixel having two blue light emitting areas, FIG. 27 (C) shows a unit pixel having two red light emitting areas, and FIG. 27 (D) shows a unit pixel having two green light emitting areas.

Specifically, the unit pixel in FIG. 27(B) includes two blue openings OPb of the pixel defining layer 380 and two blue second opening OPCFb of the color filter. At this time, the two blue openings OPb of the pixel defining layer 380 may have different eccentricities and different directions of their major axes.

Additionally, the unit pixel in FIG. 27 (C) includes two red openings OPr of the pixel defining layer 380 and two red second openings OPCFr of the color filter. At this time, the two red openings OPr of the pixel defining layer 380 may have different eccentricities and different directions of their major axes.

The unit pixel in FIG. 27 (D) includes two green openings OPg of the pixel defining layer 380 and two green second openings OPCFg of the color filter. At this time, the two green openings OPg of the pixel defining layer 380 may have different eccentricities and different directions of their major axes.

A plurality of openings OPr, OPg, OPb of the pixel defining layer 380 and a plurality of second openings OPCFr, OPCFg, OPCFb of the color filter, as described in various embodiments, or modifications thereof may be applied to the unit pixel of FIG. 27.

In the above, we focused on an embodiment in which the opening OP of the pixel defining layer 380 has an oval shape and the second opening OPCF of the color filter has a circular shape. However, depending on an embodiment, they may have a polygonal shape rather than an oval or circular shape. That is, depending on an embodiment, the second opening OPCF of the color filter has a polygonal shape, and the opening OP of the pixel defining layer 380 has a polygonal shape elongated in one direction. Here, the polygon may be an n-sided polygon such as a hexagon or an octagon (n is an integer of 3 or more).

Depending on an embodiment, the polygon of the second opening OPCF of the color filter and the polygon of the opening OP of the pixel defining layer 380 may be formed in a planar shape with different numbers of vertices or sides.

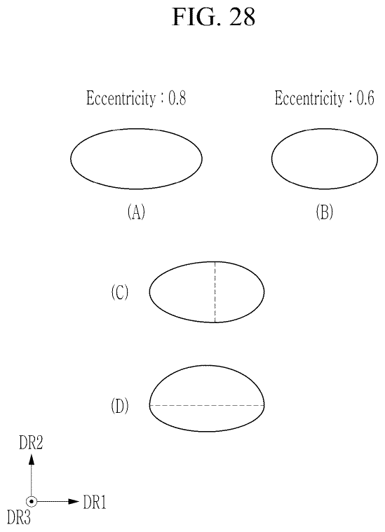

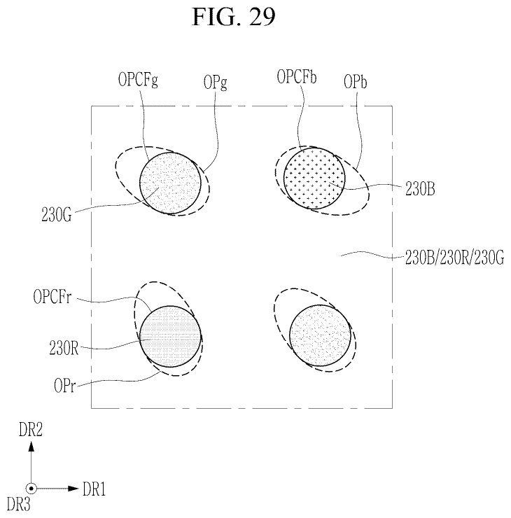

According to an embodiment, they may be formed in a shape equivalent to an ellipse, and as an example, at least two elliptical shapes with different eccentricities may be combined to form a single opening OP of the pixel defining layer 380. This will be discussed in detail with reference to FIGS. 28 and 29.

FIGS. 28 and 29 are diagrams showing a structure in which ellipses with different eccentricities are combined.

FIG. 28 is an example combining two or more ellipses with different eccentricities, which will be discussed in detail below.

In FIG. 28 (A) and (B), ellipses with different eccentricities are depicted, and in FIG. 28 (C) and (D), ellipses that combine two ellipses with different eccentricities in different ways are depicted.

FIG. 28 (A) shows an ellipse with an eccentricity of 0.8, and FIG. 28 (B) shows an ellipse with an eccentricity of 0.6. An ellipse that merges these two ellipses may have a shape like FIG. 28 (C) or (D).

In FIG. 28 (C) and (D), a dotted line is shown within the merged oval shape, and the ovals on both sides of the dotted line are parts of an ellipse with different eccentricities.

That is, FIG. 28 (C) is an example of the ellipses of FIG. 28 (A) and (B) cut along the second direction DR2 and then combined. FIG. 28 (D) is an example of FIG. 28 (A) and (D) cutting the ellipses along the first direction DR1 and then combining them. The method of combining two ellipses with different eccentricities is not limited thereto and the ellipses with different eccentricitis may be combined in various ways.

The second openings OPCFr, OPCFg, OPCFb of the color filter and the openings OPr, OPg, OPb of the pixel defining layer 380 may have the combined elliptical shape as shown in FIG. 28 (C). FIG. 29 depicts an arrangement of the second openings and the openings, both of which are formed in the combined elliptical shape of FIG. 28 (C), arranged in a various major axes directions.

In an embodiment of FIG. 29, only one unit pixel is shown, and one unit pixel includes one red opening OPr and a corresponding second opening OPCFr, one blue opening OPb and a corresponding second opening OPCFb, and two green openings OPg and corresponding two second openings OPCFg.

In an embodiment of FIG. 29, the major axis directions of the opening OP r, OPg, OPb of the pixel defining layer 380 may be different.

As shown in FIG. 29, in an embodiment that uses an ellipse that is a combination of two ellipses with different eccentricities, the angle formed by each major axis of the openings OPr, OPg, OPb of the pixel defining layer 380 may have four or more angles, and additionally, the angle formed by the major axis may be arranged at intervals of 45 degrees or less.

Additionally, the eccentricities of the two ellipses used for merging may vary, so the size of the merged ellipses may also vary. Additionally, depending on an embodiment, two ovals with different eccentricities for each color may be combined, and even if they are the same color, two ovals with different eccentricities may be combined to form various ellipses.

In the embodiments of FIGS. 28 and 29, the illustration and description focus on the embodiment of merging two different oval shapes. However, depending on an embodiment, it is possible to merge two or more oval shapes with different eccentricities.

As described above, the embodiment of merging two or more elliptical shapes also results in varying horizontal distances between the boundaries of the openings OPr, OPg, OPb of the pixel defining layer 380 and the boundaries of the corresponding second openings OPCFr, OPCFg, OPCFb of the color filter, depending on their positions. This variation mitigates reflection characteristics and produces a blurred reflective diffraction pattern and makes ring shapes less distinct and color separation less noticeable to the user. Consequently, this leads to improved display quality compared to the comparative examples.

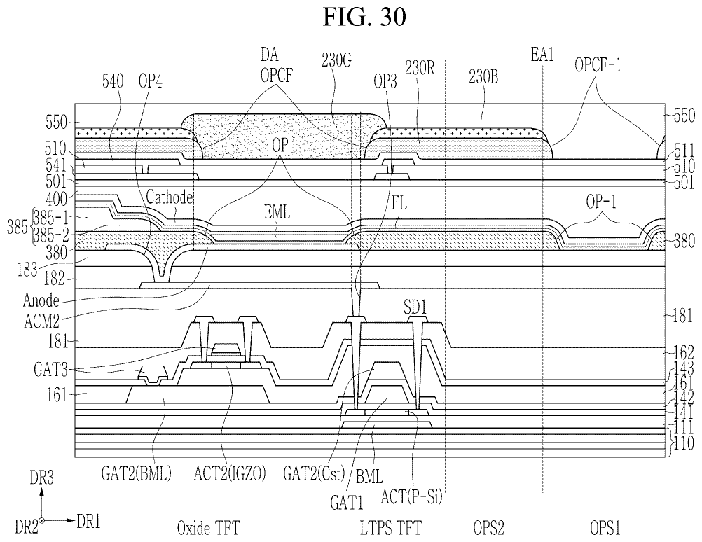

Hereinafter, with reference to FIG. 30, a more detailed cross-sectional structure of an embodiment in which the color filters 230R, 230G, 230B are formed by overlapping each other and does not include a light blocking layer will be explained.

FIG. 30 shows an embodiment in which a light blocking area of the color filter is formed by overlapping the blue color filter 230B and a red color filter 230R.

FIG. 30 is a cross-sectional view of a light emitting display device according to an embodiment.

In FIG. 30, in addition to the stacked structure of the display area DA, the stacked structure of the first component area EA1 is also shown.

A light emitting display device can be largely divided into a lower panel layer and an upper panel layer. The lower panel layer may include a light emitting diode and a pixel circuit unit that make up the pixel, and may include the encapsulation layer 400 that covers the light emitting diode and the pixel circuitry.

Here, the pixel circuit unit includes the second organic layer 182 and the third organic layer 183, and refers to the lower part thereof. The light emitting diode is disposed on the third organic layer 183, and the encapsulation layer 400 is disposed on the light emitting diode. The structure disposed on the encapsulation layer 400 may correspond to the upper panel layer.

Referring to FIG. 30, a metal layer BML is located on the substrate 110.

The substrate 110 may include a material that has rigid properties and does not bend, such as glass, or may include a flexible material that can bend, such as plastic or polyimide.

In case of a flexible substrate being used, as shown in FIG. 30, the substrate 110 may include a double-layer structure of polyimide and a barrier layer formed of an inorganic insulating material thereon.

The metal layer BML may be formed in a position that overlaps a channel of the first semiconductor layer in a driving transistor T1, and is also called a lower shielding layer. The metal layer BML may include a metal or metal alloy such as copper (Cu), molybdenum (Mo), aluminum (Al), or titanium (Ti).

A buffer layer 111 covering the substrate 110 and the metal layer BML is disposed on the substrate 110. The buffer layer 111 serves to block the penetration of impurities into the first semiconductor layer ACT(P-Si), and may be an inorganic insulating layer including a silicon oxide (SiOₓ), a silicon nitride (SiNₓ), or a silicon oxynitride (SiOₓN_{y}).

A first semiconductor layer ACT(P-Si) including a silicon semiconductor (e.g., polycrystalline semiconductor (P-Si)) is disposed on the buffer layer 111. The first semiconductor layer ACT(P-Si) includes a channel of a polycrystalline transistor LTPS TFT including the driving transistor T1, and a first region and a second region positioned on both sides thereof. Here, the polycrystalline transistor LTPS TFT may include not only the driving transistor T1 but also various switching transistors or compensation transistors. Additionally, the first semiconductor layer ACT(P-Si) may include first and second regions, on both sides of the channel, that have conductive characteristics through plasma treatment or doping. The first and second regions of the first semiconductor layer ACT(P-Si) may serve as a first electrode and a second electrode of the transistor.

A first gate insulating layer 141 may be disposed on the first semiconductor layer ACT(P-Si). The first gate insulating layer 141 may be an inorganic insulating layer including a silicon oxide (SiOₓ), a silicon nitride (SiNₓ), or a silicon oxynitride (SiOₓN_{y}).

A first gate conductive layer GAT1 including the gate electrode of a polycrystalline transistor LTPS TFT may be disposed on the first gate insulating layer 141. The first gate conductive layer GAT1 may further include a first scan line or an emission control line. The first gate conductive layer may include a metal or metal alloy such as copper (Cu), molybdenum (Mo), aluminum (Al), or titanium (Ti), and may be composed of a single layer or multiple layers.

After forming the first gate conductive layer GAT1, a plasma treatment or doping process may be performed to make the exposed area of the first semiconductor layer conductive. That is, the first semiconductor layer ACT(P-Si) covered by the first gate conductive layer GAT1 does not turn conductive, and the first semiconductor layer ACT not covered by the first gate conductive layer GAT1 may have the same characteristics as the conductive layer.

A second gate insulating layer 142 may be disposed on the first gate conductive layer GAT1 and the first gate insulating layer 141. The second gate insulating layer 142 may be an inorganic insulating layer including a silicon oxide (SiOₓ), a silicon nitride (SiNₓ), or a silicon oxynitride (SiOₓN_{y}).

A second gate conductive layer including a first electrode GAT2(Cst) of a storage capacitor Cst and a lower shielding layer GAT2(BML) of the oxide transistor Oxide TFT may be disposed on the second gate insulating layer 142.

The lower shielding layer GAT2(BML) of the oxide transistor Oxide TFT is disposed below a channel of an oxide transistor Oxide TFT and serves to shield from light or electromagnetic interference provided to the channel from the bottom.

The first electrode GAT2(Cst) of the storage capacitor Cst overlaps with the gate electrode GAT1 of the driving transistor T1 to form the storage capacitor Cst.

Depending on the embodiment, the second gate conductive layer may further include a scan line, a control line, or a voltage line. The second gate conductive layer may include a metal or metal alloy such as copper (Cu), molybdenum (Mo), aluminum (Al), or titanium (Ti), and may be composed of a single layer or multiple layers.

A first interlayer insulating layer 161 may be disposed on the second gate conductive layer. The first interlayer insulating layer 161 may include an inorganic insulating layer including a silicon oxide (SiOₓ), a silicon nitride (SiNₓ), or a silicon oxynitride (SiOₓN_{y}). Depending on an embodiment, the inorganic insulating material may be formed thickly.

An oxide semiconductor layer ACT2 (IGZO) including a channel, a first region, and a second region of an oxide transistor Oxide TFT may be disposed on the first interlayer insulating layer 161.

A third gate insulating layer 143 may be disposed on the oxide semiconductor layer ACT2 (IGZO). The third gate insulating layer 143 may be disposed on the entire surface of the oxide semiconductor layer ACT2 (IGZO) and the first interlayer insulating layer 161. The third gate insulating layer 143 may include an inorganic insulating layer comprising a silicon oxide (SiOₓ), a silicon nitride (SiNₓ), or a silicon oxynitride (SiOₓN_{y}).

A third gate conductive layer GAT3 including the gate electrode of an oxide transistor Oxide TFT may be disposed on the third gate insulating layer 143. The gate electrode of an oxide transistor Oxide TFT may overlap the channel of the oxide semiconductor layer ACT2 (IGZO). The third gate conductive layer GAT3 may further include a scan line or a control line, and may additionally include a connection electrode connected to the lower shielding layer GAT2 BML of the oxide transistor Oxide TFT. The third gate conductive layer GAT3 may include a metal or metal alloy such as copper (Cu), molybdenum (Mo), aluminum (Al), or titanium (Ti), and may be composed of a single layer or multiple layers.

A second interlayer insulating layer 162 may be disposed on the third gate conductive layer GAT3. The second interlayer insulating layer 162 may have a single-layer or multi-layer structure. The second interlayer insulating layer 162 may include an inorganic insulating material such as a silicon nitride (SiNₓ), a silicon oxide (SiOₓ), or a silicon nitride (SiOₓN_{y}), and may include an organic material depending on the embodiment.

A first data conductive layer SD1 is disposed on the second interlayer insulating layer 162 and includes a connection electrode that can be connected to the first and second regions of each of the polycrystalline transistor LTPS TFT and the oxide transistor Oxide TFT. The first data conductive layer SD1 may include a metal or metal alloy such as aluminum (Al), copper (Cu), molybdenum (Mo), or titanium (Ti), and may be composed of a single layer or multiple layers.

The first organic layer 181 may be disposed on the first data conductive layer SD1. The first organic layer 181 may be an organic insulating layer including an organic material, and the organic material includes one or more materials selected from the group consisting of polyimide, polyamide, acrylic resin, benzocyclobutene, and phenol resin.

A second data conductive layer including an anode connection electrode ACM2 may be disposed on the first organic layer 181. The second data conductive layer may include a data line or a driving voltage line. The second data conductive layer SD2 may include a metal or metal alloy such as aluminum (Al), copper (Cu), molybdenum (Mo), or titanium (Ti), and may be composed of a single layer or multiple layers.

Above the second data conductive layer, the second organic layer 182 and the third organic layer 183 are disposed, and an anode connection opening OP4 is formed in the second organic layer 182 and the third organic layer 183. The anode connection electrode ACM2 is electrically connected to the anode Anode through the anode connection opening OP4. The second organic layer 182 and the third organic layer 183 may be organic insulating layers and may include one or more materials selected from the group consisting of polyimide, polyamide, acrylic resin, benzocyclobutene, and phenol resin. Depending on an embodiment, the third organic layer 183 may be omitted.

The pixel defining layer 380 may be disposed on the anode and has an opening OP extending to the anode and covers at least a portion of the anode. The pixel defining layer 380 may be a black pixel defining layer formed of a black organic material to prevent light applied from the outside from being reflected back to the outside. Depending on an embodiment, the pixel defining layer 380 may be formed of a transparent organic material. The pixel defining layer 380 may include a negative-type black organic material and a black pigment.

A spacer 385 is disposed on the pixel defining layer 380. The spacer 385 may include a first part 385-1 that is tall and located in a narrow area, and a second part 385-2 that is low in height and is located in a wide area. Unlike the pixel defining layer 380, the spacer 385 may be formed of a transparent organic insulating material. Depending on an embodiment, the spacer 385 may be formed of a positive-type transparent organic material.

A functional layer FL and a cathode are sequentially formed on the anode, a spacer 385 and the pixel defining layer 380, and are formed sequentially in the display area DA and the first component area EA1. The functional layer FL and the cathode may be located in all areas.

The light emitting layer EML is located between the functional layer FL and the light emitting layer EML and may be positioned only within the opening OP of the pixel defining layer 380.

Hereinafter, the functional layer FL and the light emitting layer EML, collectively, may be referred to as the intermediate layer.

The functional layer FL may include at least one of an electron injection layer, an electron transport layer, a hole transport layer, and a hole injection layer. The hole injection layer and the hole transport layer may be disposed below the light emitting layer EML, and an electron transport layer and an electron injection layer may be disposed on the light emitting layer EML.

The encapsulation layer 400 is disposed on the cathode. The encapsulation layer 400 may include at least one inorganic layer and at least one organic layer. Depending on an embodiment, the encapsulation layer 400 may have a triple-layer structure including a first inorganic encapsulation layer, an organic encapsulation layer, and a second inorganic encapsulation layer. The encapsulation layer 400 may be used to protect the light emitting layer EML from moisture or oxygen that may enter from the outside. Depending on an embodiment, the encapsulation layer 400 may include a structure in which an inorganic layer and an organic layer are further sequentially stacked.

Sensing insulating layers 501, 510, 511 and the plurality of sensing electrodes 540, 541 are disposed on the encapsulation layer 400 for touch detection. In an embodiment of FIG. 30, touch can be sensed in a capacitive manner using two sensing electrodes 540 and 541.

Specifically, a first sensing insulating layer 501 is disposed on the encapsulation layer 400, and the plurality of sensing electrodes 540 and 541 are formed thereon. The plurality of sensing electrodes 540 and 541 may be insulated with the second sensing insulating layer 510 interposed therebetween, and some of the plurality of sensing electrodes 540 and 541 may be electrically connected through an opening located in the second sensing insulating layer 510. The sensing electrodes 540 and 541 may include metal or metal alloy such as aluminum (Al), copper (Cu), silver (Ag), gold (Au), molybdenum (Mo), titanium (Ti), and tantalum (Ta), and it may include a single layer or multiple layers. A third sensing insulating layer 511 is disposed on the sensing electrode 540.

Color filters 230R, 230G, 230B are disposed on the third sensing insulating layer 511.

In an embodiment of FIG. 30, a light blocking layer is not included. Instead of the light blocking layer, the overlapped color filters 230R, 230B may be disposed on the third sensing insulating layer 511, and may overlap with the sensing electrodes 540, 541 on a plane. The overlapped color filters 230R, 230B may include a second opening OPCF, and the second opening OPCF of the overlapped color filters 230R, 230B overlaps with the opening OP of the pixel defining layer 380 on a plane.

Additionally, the second opening OPCF of the overlapped color filters 230R, 230B may be wider than the opening OP of the pixel defining layer 380. As a result, the anode that overlaps the opening OP of the pixel defining layer 380 (i.e., exposed by the opening OP of the pixel defining layer 380) also overlaps the color filters 230R, 230B. This is to ensure that the anode and the light emitting layer EML capable of displaying an image are not obscured by the overlapped color filters 230R, 230B and the sensing electrodes 540 and 541. Additionally, the overlapped color filters 230R, 230B may overlap with the anode connection opening OP4 on a plane.

A single color filter may be positioned within the second opening OPCF of the overlapped color filters 230R, 230B. For example, in FIG. 30, the green color filter 230G is disposed within the second opening OPCF of the overlapped color filters 230R and 230B. Depending on an embodiment, the color filters 230R, 230G, 230B may be replaced with a color conversion layer or may further include a color conversion layer. The color conversion layer may include quantum dots.

A planarization layer 550 covering the color filters 230R, 230G, 230B is disposed on the color filters 230R, 230G, 230B. The planarization layer 550 is used to planarize the upper surface of the light emitting display device, and may be a transparent organic insulating layer including one or more materials selected from the group consisting of polyimide, polyamide, acrylic resin, benzocyclobutene, and phenol resin.

Depending on an embodiment, a low refractive layer and an additional planarization layer may be further disposed on the planarization layer 550 to improve front visibility and light output efficiency of the display device. Light can be refracted and emitted toward the front by the low refractive layer and the additional planarization layer with high refractive characteristics. In this case, depending on an embodiment, the planarization layer 550 may be omitted and the low refractive layer and the additional planarization layer may be disposed directly on the color filter.

In this embodiment, a polarizing plate is not included on top of the planarization layer 550. In other words, the polarizer may play a role in preventing display quality from deteriorating when external light is incident and reflected by an anode, etc. However, in this embodiment, the side of the anode is covered with the pixel defining layer 380 to reduce the degree of reflection from the anode, and the overlapped color filters 230R, 230B are also formed to reduce the degree of incident light. In short, the display panel DP according to an embodiment already includes a structure that prevents deterioration of display quality due to reflection. Therefore, there is no need to separately form the polarizer on the front of the display panel DP.

Depending on an embodiment, a cover window (see WU in FIG. 3) including an anti-reflection layer (see ARL in FIG. 3) may be disposed on top of the planarization layer 550.

In FIG. 30, in addition to the stacked structure of the display area DA, the cross-sectional structure of the first component area EA1, which is formed to allow light to transmit through a portion of the display area DA, is also shown.

In FIG. 30, the first component area EA1 is divided into a first optical sensor area (OPS1; also referred to as a transmissive optical sensor area) and a second optical sensor area (OPS2; also referred to as a non-transmissive optical sensor area). The first optical sensor area OPS1 may include additional openings OP-1, OPCF-1 so that light may pass through the additional openings OP-1, OPCF-1. In contrast, the second optical sensor area OPS2 may overlap with the black pixel defining layer 380 and the light blocking area of the color filter, where at least two color filters are overlapped. So, the second optical sensor area OPS2 may not transmit light therethrough.

Both the first optical sensor area OPS1 and the second optical sensor area OPS2 of the first component area EA1 may not include a layer that blocks light, such as a metal layer or a semiconductor layer. For reference, the first optical element (ES1; refer to FIG. 2) is positioned on the back of the first component area EA1, and the front of the light emitting display device may be detected through the first optical sensor area OPS1 located in the first component area EA1.

Specifically, the layered structure of the first component area EA1 is as follows.

A buffer layer 111, which is an inorganic insulating layer, is disposed on the substrate 110, and the first gate insulating layer 141 and the second gate insulating layer 142, which are inorganic insulating layers, are sequentially positioned thereon. Additionally, the first interlayer insulating layer 161, the third gate insulating layer 143, and the second interlayer insulating layer 162, which are inorganic insulating layers, are sequentially stacked on the second gate insulating layer 142.

On the second interlayer insulating layer 162, a first organic layer 181, a second organic layer 182, and a third organic layer 183, which are organic insulating layers, are sequentially stacked.

A functional layer FL may be disposed on the third organic layer 183, and a cathode may be disposed on the third organic layer 183.

The encapsulation layer 400 is disposed on the cathode, and sensing insulating layers 501, 510, 511 are sequentially positioned on top of the cathode. The encapsulation layer 400 may have a triple-layer structure sequentially including an inorganic encapsulation layer, an organic encapsulation layer, and an inorganic encapsulation layer. Additionally, the sensing insulating layers 501, 510, 511, which are disposed on the encapsulation layer 400, may all be inorganic insulating layers.

The planarization layer 550 may be disposed on the sensing insulating layers 501, 510, 511.

The first component area EA1 as described above may not include a metal layer, a first semiconductor layer, a first gate conductive layer, a second gate conductive layer, an oxide semiconductor layer, a third gate conductive layer, a first data conductive layer, and a second data conductive layer, and the anode. Additionally, the light emitting layer EML and the sensing electrodes 540 and 541 are not formed in the first component area EA1.

Additionally, in the first optical sensor area OPS1 of the first component area EA1, additional openings OP-1, OPCF-1 are formed in the pixel defining layer 380 and the light blocking area of the color filter, respectively. Thus, the first optical sensor area OPS1 may not include the black pixel defining layer 380, and a color filter. As a result, light may pass through the first optical sensor area OPS1.

On the other hand, the second optical sensor area OPS2 of the first component area EA1 does not have additional openings OP-1, OPCF-1, and overlaps with the black pixel defining layer 380 and the light blocking area of the color filter to transmit light. As a result, light may not pass through the second optical sensor area OPS2.

In the above, we have looked at an embodiment in which a total of three organic layers are formed, and an anode connection opening is formed in the second organic layer and the third organic layer. However, at least two organic layers may be formed, and the anode connection opening may be positioned in the upper organic layer located away from the substrate, and the lower organic layer opening may be positioned in the lower organic layer.

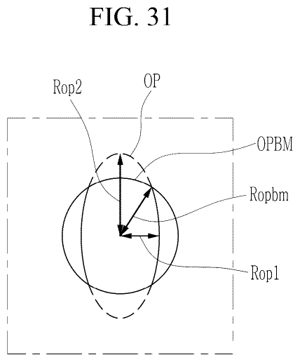

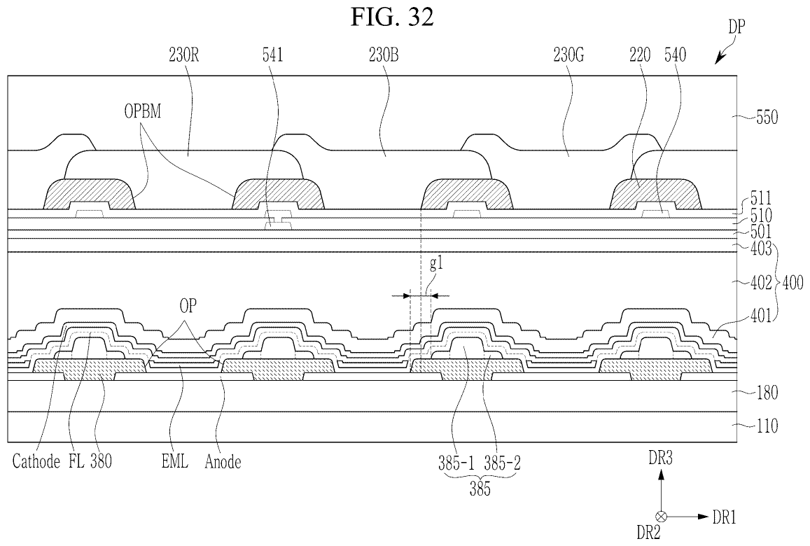

In the above, we looked at an embodiment in which two or more color filters are overlapped to form a light blocking area of the color filter, and a light blocking layer is not included. However, a light blocking layer may be included, and the second opening may be located in the light blocking layer. This embodiment will be explained through FIGS. 31 and 32.

First, let's look at the planar structure with reference to FIG. 31.

FIG. 31 is a plan view of a portion of a display panel according to an embodiment.

FIG. 31 depicts an opening OP of the pixel defining layer 380 and a second opening OPBM of a light blocking layer corresponding thereto. The second opening OPBM of the light blocking layer has a circular shape, and the opening OP of the pixel defining layer 380 has an oval shape. Additionally, the second opening OPBM of the light blocking layer overlaps a portion of the opening OP of the pixel defining layer 380, and the remaining portion of the opening OP is covered with a black light blocking layer (see 220 in FIG. 32). As a result, the light emitting layer positioned within the opening OP of the pixel defining layer 380 may be partially obscured by a light blocking layer. In FIG. 31, part of the opening OP of the pixel defining layer 380 is depicted in a dotted line to indirectly show that the corresponding part is positioned below and covered by the light blocking layer.

In the embodiment of FIG. 31, due to errors during actual processing, the portion of the opening OP of the pixel defining layer 380 that is obscured by the light blocking layer may not be constant on both the top and bottom, and the area on one side may be larger.

Additionally, one side of the opening OP of the pixel defining layer 380 may be positioned within or in contact with the second opening OPBM of the light blocking layer due to the processing error, and only the other side may be covered by the light blocking layer.

As shown in FIG. 31, if a portion of the opening OP of the pixel defining layer 380 is covered by a light blocking layer, the light emitted from the light emitting layer within the opening OP may not be provided to the front, which may be bad in terms of light efficiency. However, as the size of the opening OP of the pixel defining layer 380 is related to the lifespan of the light emitting layer located therein, the size of the opening OP may not be reduced in order to maintain the lifespan at a certain level.

Referring to FIG. 31, the length of the major axis of the opening OP of the pixel defining layer 380 is shown as Rop2, and the length of the minor axis is shown as Rop1. The radius of the second opening OPBM of the light blocking layer is shown as Ropbm. Therefore, the distance from the point where the boundaries of the two openings meet to the center is the same as Ropbm. But at other locations, the boundary of the opening OP of the pixel defining layer 380 is positioned farther from or closer to the center.

According to an embodiment, the major-axis direction of the opening OP of the pixel defining layer 380 may be variously arranged, and the angle formed by the major axis may have four or more angles. The angle formed by the major axis may be arranged at intervals of less than 45 degrees. The angles formed by the major axis may be arranged at regular intervals, or may be arranged at irregular intervals.

Since elliptical shapes have different shapes depending on eccentricity even if they have the same area, depending on an embodiment, the opening OP of the pixel defining layer 380 may be formed as an ellipse with different eccentricities.

The opening OP of the pixel defining layer 380 and the second opening OPBM of the light blocking layer corresponding thereto may have horizontal spacing that varies in a range from 0 μm to 20 μm.

Depending on an embodiment, the opening OP of the pixel defining layer 380 may be formed in a polygonal shape elongated in one direction. Examples of polygons may include n-sided polygons such as hexagons and octagons, where n may be an integer of 3 or more, and the second opening OPBM of the light blocking layer may be formed as a corresponding n-sided polygon or an n-sided polygon having different shapes.

The embodiment of FIG. 31 differs only in that the second opening is positioned in the light blocking layer. However, as the second opening OPBM is formed in a circular shape, and the opening OP of the pixel defining layer 380 is formed in an oval shape, similar to what was described above, the diffraction patterns caused by the non-uniform distances between the two openings may vary. As theses individual diffraction patterns mix, the overall diffraction pattern becomes blurred. As a result, it is difficult for users to easily recognize the diffraction pattern, and the degree of degradation of the display quality may be reduced.

A cross-sectional structure in which a light blocking layer includes a second opening OPBM will be explained in detail with reference to FIG. 32.

FIG. 32 is a schematic cross-sectional view of a display panel according to an embodiment.

FIG. 32 is a drawing corresponding to FIGS. 7 and 19, in which a light blocking layer 220 is disposed below the color filters 230R, 230G, 230B, and the second opening OPBM is also formed in a portion where the light blocking layer 220 has been removed. One of the color filters 230R, 230G, 230B is formed within the second opening OPBM of the light blocking layer 220.

The explanation focusing on the different parts of FIG. 32 from FIGS. 7 and 19 is as follows.

The light blocking layer 220 and color filters 230R, 230G, 230B are disposed on the third sensing insulating layer 511.

The light blocking layer 220 may be positioned to overlap the sensing electrodes 540 and 541 in a plane, and may be positioned not to overlap the anode in a plane. This is to ensure that the anode and the light emitting layer EML capable of displaying an image are not obscured by the light blocking layer 220 and the sensing electrodes 540 and 541.

The light blocking layer 220 may include a second opening OPBM. In a plan view, the second opening OPBM of the light blocking layer 220 may be formed in a circular shape, and the opening OP of the corresponding pixel defining layer 380 may be formed in an oval shape. One side of the light blocking layer 220 may be disposed inward from a corresponding side of the pixel defining layer 380 or may be disposed outward according to the cutting cross-sectional line. FIG. 32 depicts a cross-section where one side of the light blocking layer 220 is disposed outward from a corresponding side of the pixel defining layer 380.

Also, one side of the spacer 385 is disposed inward by a certain distance g-1 from the corresponding side of the pixel defining layer 380, and the spacer 385 may be disposed inward from one side of the light blocking layer 220. As a result, the spacer 385 may not be visible because it is obscured by the light blocking layer 220 when viewed from the front of the display panel DP.

When external light is incident, it may pass through the second opening OPBM of the light blocking layer 220 and then be reflected on the sidewall of the opening OP of the pixel defining layer 380. The sidewall of the opening OP of the pixel defining layer 380 is curved and color separation occurs depending on the position of reflection, resulting in the reflected light appearing in various colors, such as a rainbow. This color-separated reflected light may easily catch the user's eye and may degrade the display quality. So, in an embodiment of the present disclosure, as in FIG. 31, the opening OP of the pixel defining layer 380 may be formed in an oval shape, and the second opening OPBM of the light blocking layer 220 may be formed in a circular shape to mitigate the degree of diffraction of light reflected from the sidewalls of the opening OP of the pixel defining layer 380 and to improve the spread of diffraction patterns, thereby reducing the degradation of display quality due to reflected light.

Color filters 230R, 230G, 230B are disposed on the sensing insulating layers 501, 510, 511 and the light blocking layer 220. The color filters 230R, 230G, 230B may include a red color filter 230R that allows red light to pass through, the green color filter 230G that allows green light to pass through, and the blue color filter 230B that allows blue light to pass through. Each of the color filters 230R, 230G, 230B may be positioned to overlap the anode of the light emitting diode on a plane. Since the light emitted from the light emitting layer EML may change to a corresponding color as it passes through a color filter, all light emitted from the light emitting layer EML may have the same color. However, the light emitting layer EML may emit light of different colors, and the displayed color may be enhanced after passing through the color filter of the same color.

The light blocking layer 220 may be positioned between each color filter 230R, 230G, 230B. Depending on an embodiment, the color filters 230R, 230G, 230B may be replaced with a color conversion layer or may further include a color conversion layer. The color conversion layer may include quantum dots.

The planarization layer 550 covering the color filters 230R, 230G, 230B is disposed on the color filters 230R, 230G, 230B. The planarization layer 550 is used to planarize the upper surface of the light emitting display panel and may be a transparent organic insulating layer including one or more materials selected from the group consisting of polyimide, polyamide, acrylic resin, benzocyclobutene, and phenol resin.

Depending on an embodiment, a low refractive layer and an additional planarization layer may be further disposed on the planarization layer 550 to improve front visibility and light output efficiency of the display panel. Light may be refracted and emitted toward the front by the low refractive layer and the additional planarization layer with high refractive characteristics. Depending on an embodiment, the planarization layer 550 may be omitted and the low refractive layer and the additional planarization layer may be disposed directly on the color filter 230.

In this embodiment, a cover window (see WU in FIG. 3) including an anti-reflection layer (see ARL in FIG. 3) may be positioned on top of the planarization layer 550, and a polarizer may not be included. The polarizer may prevent the degradation of the display quality when external light is incident and reflected by the anode or the sidewall of the opening OP of the pixel defining layer 380, which is visible to the user. However, the polarizer is the disadvantageous in consuming more power to display a certain luminance because the polarizer not only reduces the reflection of external light but also reduces the light emitted from the light emitting layer EML. In order to reduce power consumption, the light emitting display device according to an embodiment may not include a polarizer.

In addition, in an embodiment, the side of the anode is covered with the pixel defining layer 380 to reduce the degree of reflection from the anode, and the light blocking layer 220 is also formed to reduce the degree of incident light, thereby reducing the amount of light incident on the anode. So, the display panel DP according to an embodiment already includes a structure that prevents the degradation of display quality. Therefore, there is no need to separately form the polarizer on the front of the light emitting display panel DP.

As shown in FIG. 31 and FIG. 32, forming the second opening of the light blocking layer in a circular shape may be modified and applied in various embodiments, similar to the previously described second opening of the color filter. These modifications include different shapes, various direction of the major axis, different eccentricities, and combining two or more ellipses.

Although the embodiments of the present disclosure have been described in detail above, the scope of the present disclosure is not limited thereto, and various modifications and improvements made by those skilled in the art using the basic concepts of the present disclosure defined in the following claims are also possible.

What is claimed is:

1. A light emitting display device, comprising:
a substrate;
a plurality of anodes disposed on the substrate;
a pixel defining layer including a plurality of first openings, each of the plurality of first openings corresponding to each of the plurality of anodes;
a plurality of light emitting layers disposed in the plurality of first opening of the pixel defining layer;
a cathode disposed on the plurality of light emitting layers and the pixel defining layer;
an encapsulation layer disposed on the cathode; and
a plurality of color filters corresponding to different colors disposed on the encapsulation layer,
wherein the plurality of color filters includes a plurality of second openings and a light blocking area of a color filter,
wherein the light blocking area of the color filter includes at least two color filters overlapped with each other, and a single color filter is disposed in each of the plurality of second openings,
wherein at least some of the plurality of first openings of the pixel defining layer have an oval shape, and
wherein the plurality of second openings of the color filter, which at least partially overlaps the plurality of first openings having the oval shape, has a circular shape.

2. The light emitting display device of claim 1, wherein at least a portion of the first opening of the pixel defining layer having the oval shape overlaps the light blocking area of the color filter on a plane.

3. The light emitting display device of claim 2, wherein the second opening of the color filter and the first opening of the pixel defining layer meet each other at least two times.

4. The light emitting display device of claim 2, wherein the second opening of the color filter is positioned within the first opening of the pixel defining layer having the oval shape in a plan view.

5. The light emitting display device of claim 2, wherein a length of a minor axis of the first opening of the pixel defining layer having the oval shape is shorter than a diameter of the second opening of the color filter, and
a length of a major axis of the first opening of the pixel defining layer is longer than the diameter of the second opening of the color filter.

6. The light emitting display device of claim 5, wherein the second opening of the color filter and the first opening of the pixel defining layer intersect each other at least four times.

7. The light emitting display device of claim 1, wherein the first opening of the pixel defining layer having the oval shape is positioned within the second opening of the color filter having the circular shape in a plan view.

8. The light emitting display device of claim 7, wherein the second opening of the color filter and the first opening of the pixel defining layer meet each other at least two times.

9. The light emitting display device of claim 1, wherein the plurality of first openings or the plurality of second openings includes four or more major axis angles, and
the angle formed by the major axes of two first openings among the plurality of first openings or the angle formed by the major axes of the two second openings among the plurality of second openings is 45 degrees or less.

10. The light emitting display device of claim 1, wherein each of the plurality of first openings or each of the plurality of second openings has eccentricity in a range from 0.2 to 0.85.

11. The light emitting display device of claim 1, wherein a gap between the first opening and the second opening that overlaps the first opening in a plane is in a range from 0 μm to 20.

12. The light emitting display device of claim 1, wherein the first opening or the second opening has a planar shape that merges at least two oval shapes with different eccentricities.

13. The light emitting display device of claim 12, wherein the first opening or the second opening has a planar shape including a first ellipse with first eccentricity and a second ellipse with second eccentricity.

14. The light emitting display device of claim 1, wherein the light blocking area of the color filter includes a blue color filter and a red color filter overlapped each other, and
each of the plurality of second openings accommodates one of the blue color filter, the red color filter, and a green color filter.

15. The light emitting display device of claim 1, wherein the light blocking area of the color filter includes a blue color filter, a red color filter, and a green color filter overlapped each other, and
each of the plurality of second openings accommodates one of the blue color filter, the red color filter, and the green color filter.

16. A light emitting display device, comprising:
a substrate;
a plurality of anodes disposed on the substrate;
a pixel defining layer including a plurality of first openings, each of the plurality of first openings corresponding to each of the plurality of anodes;
a plurality of light emitting layers disposed in the plurality of first openings of the pixel defining layer;
a cathode disposed on the plurality of light emitting layers and the pixel defining layer;
an encapsulation layer disposed on the cathode; and
a light blocking layer disposed on the encapsulation layer and including a plurality of second openings, each of the plurality of second openings of the light blocking layer corresponding to each of the plurality of first openings,
wherein at least some of the plurality of first openings of the pixel defining layer has an oval shape, and
wherein the plurality of second openings of the light blocking layer, which at least partially overlap the plurality of first openings having the oval shape, has a circular shape.

17. The light emitting display device of claim 16, wherein at least a portion of the first opening of the pixel defining layer having the oval shape overlaps the light blocking layer in a plane.

18. The light emitting display device of claim 17, wherein the second opening of the light blocking layer is positioned within the first opening of the pixel defining layer having the oval shape in a plan view.

19. The light emitting display device of claim 17, wherein a length of a minor axis of the first opening of the pixel defining layer having the oval shape is shorter than a diameter of the second opening of the light blocking layer, and
a length of a major axis of the first opening of the pixel defining layer is longer than the diameter of the second opening of the light blocking layer.

20. The light emitting display device of claim 16, wherein the first opening of the pixel defining layer having the oval shape is positioned within the second opening of the light blocking layer having a circular shape in a plan view.
